(19) United States
(12) Patent Application Publication
(10) Pub. No.: US 2025/0063688 A1
(43) Pub. Date: Feb. 20, 2025

(54) OPTIMIZED CHIP COOLING INFRASTRUCTURE

(71) Applicant: Microsoft Technology Licensing, LLC, Redmond, WA (US)

(72) Inventors: Eric C. PETERSON, Woodinville, WA (US); Husam Atallah ALISSA, Redmond, WA (US); Sean Patrick ABBOTT, Redmond, WA (US)

(21) Appl. No.: 18/517,189

(22) Filed: Nov. 22, 2023

Related U.S. Application Data
(60) Provisional application No. 63/533,515, filed on Aug. 18, 2023.

(51) Int. Cl. H05K 7/20

(52) U.S. Cl. CPC H05K 7/20272; H05K 7/20254; H05K 7/20781

(57) ABSTRACT

A cold plate assembly for cooling a computing device includes a first cooling structure and a second cooling structure. The first cooling structure is configured to provide cooling from a flow of first coolant to a first temperature section of the computing device. The second cooling structure is connected to the first cooling structure and is configured to provide cooling from a flow of second coolant to a second temperature section of the computing device. The second temperature section has a lower temperature threshold than the first temperature section. The cold plate assembly includes a thermal barrier between the first cooling structure and the second cooling structure.

### CROSS-REFERENCE TO RELATED APPLICATIONS

This application claims priority to and the benefit of U.S. Provisional Patent Application No. 63/533,515, filed on Aug. 18, 2023, which is hereby incorporated by reference in its entirety.

### BACKGROUND

The advancement of computing technology has led to the miniaturization and increased power densities of computer chips. Some chips, such as those used in Artificial Intelligence (AI) computing, implement memory components in close proximity to processing components on a same chip. Often, the processing components and memory components have different cooling requirements. For example, the processing components may typically have a substantially exposed upper surface area, which facilitates typical cold-plate style cooling to conduct heat away from the processor throughout the entire surface area of the processor. As the need for increased memory capacity grows, however, vertically stacked, high-bandwidth memory (HBM) is becoming increasingly prevalent in AI computing chips. The stacked configuration of HBM makes it difficult to efficiently cool each layer of the stack by the conventional cold plate cooling, as lower layers of the HBM are at least partially covered and cannot contact a cold plate positioned on the top of the component. Thus, in order to maintain the individual memory resources of each layer within an operational temperature threshold, cooling of HBM components is typically provided at a lower temperature than what is necessary for a processing component.

Conventional cooling solutions are limited in their ability to adequately distribute heat and optimize temperature control over different sections of a chip having different thermal profiles, such as AI computing chips. For example, some conventional methods implement a single cold plate cooled to the most restrictive temperature, that of the HBMs, to cool all of the components of the chip. This technique, however, unnecessarily provides cooling to the processing components at much lower temperatures than needed. Other methods attempt to combat this by channeling coolant to flow over/past the memory components first before flowing to the processor. The result of these conventional techniques, however, is often inadequate cooling of the memory components, which can lead to premature wear and a shortened lifespan of the memory components, or throttling of the memory components to prevent overheating. Further, overcooling the processing components can result in significant and unnecessary energy expenditure, especially when considering the vast quantity of computing chips implemented in a data center. Thus, improved cooling techniques for accommodating varying temperature requirements across different sections of a single chip can be advantageous.

### SUMMARY

In some embodiments, a cold plate assembly for cooling a computing device includes a first cooling structure and a second cooling structure. The first cooling structures is configured to provide cooling from a flow of first coolant to a first temperature section of the computing device. The second cooling structure is connected to the first cooling structure and is configured to provide cooling from a flow of second coolant to a second temperature section of the computing device. The second temperature section has a lower temperature threshold than the first temperature section. The cold plate assembly further includes a thermal barrier between the first cooling structure and the second cooling structure.

In some embodiments, a cold plate assembly for cooling a computing device includes a first cooling structure and a second cooling structure. The first cooling structure has a first coolant inlet and a first coolant outlet for connecting the first cooling structure to a first coolant loop. The first cooling structure is configured to provide cooling to a first temperature section of the computing device. The second cooling structure is connected to the first cooling structure and has a second coolant inlet and a second coolant outlet for connecting the second cooling structure to a second coolant loop. The second coolant loop is at a lower temperature than the first coolant loop. The second cooling structure is configured to provide cooling to a second temperature section of the computing device. The second temperature section has a lower temperature threshold than the first temperature section. The cold plate assembly further includes a thermal barrier between the first cooling structure and the second cooling structure.

In some embodiments, a method is disclosed for cooling a computing device having a first temperature section and a second temperature section. The method includes flowing a first coolant to a first cooling structure of a cold plate assembly. The method further includes cooling the first temperature section with the first cooling structure. The method further includes flowing a second coolant to a second cooling structure of the cold plate assembly connected to the first cooling structure. The method further includes cooling the second temperature section with the second cooling structure.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description that follows. Features and advantages of the disclosure may be realized and obtained by means of the systems and methods that are particularly pointed out in the appended claims. Features of the present disclosure will become more fully apparent from the following description and appended claims, or may be learned by the practice of the disclosed subject matter as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. Understanding that the drawings depict some example embodiments, the embodiments will be described and explained with additional specificity and detail through the use of the accompanying drawings in which:

FIG. 1-1 is a perspective view of a cold plate assembly, according to at least one embodiment of the present disclosure;

FIG. 1-2 is an exploded view of the cold plate assembly of FIG. 1-1;

FIG. 2-1 is a perspective view of a server implementing a cold plate assembly, according to at least one embodiment of the present disclosure;

FIG. 2-2 is a perspective view of a server rack implementing multiple instances of the server of FIG. 2-1;

FIG. 2-3 is diagram illustrating the cold plate assembly of FIG. 2-1 connected to a coolant distribution unit as part of a coolant system;

FIG. 3 is a process diagram of a coolant system, according to at least one embodiment of the present disclosure;

FIG. 4-1 is a process diagram of a coolant system implementing a heat pump, according to at least one embodiment of the present disclosure;

FIG. 4-2 is a process diagram of a coolant system implementing a heat pump, according to at least one embodiment of the present disclosure;

FIG. 5 is a process diagram of a coolant system implanting a heat pump, according to at least one embodiment of the present disclosure;

FIG. 6 is a process diagram of a coolant system, according to at least one embodiment of the present disclosure;

FIG. 7-1 is a process diagram of one or more facility level cooling devices as described herein, according to at least one embodiment of the present disclosure;

FIG. 7-2 is a process diagram illustrating a large-scale implementation of the facility level cooling devices of FIG. 7-1 as describe herein, according to at least one embodiment of the present disclosure;

FIG. 8 illustrates a flow diagram for a method or a series of acts for cooling a computing device as described herein, according to at least one embodiment of the present disclosure;

FIG. 9 illustrates a flow diagram for a method or a series of acts for cooling a computing device as described herein, according to at least one embodiment of the present disclosure;

FIG. 10 illustrates a flow diagram for a method or a series of acts for cooling a computing device as described herein, according to at least one embodiment of the present disclosure;

FIG. 11 illustrates a flow diagram for a method or a series of acts for cooling a computing device as described herein, according to at least one embodiment of the present disclosure;

FIG. 12 illustrates a flow diagram for a method or a series of acts for cooling a computing device as described herein, according to at least one embodiment of the present disclosure.

### DETAILED DESCRIPTION

The present disclosure is generally related to systems, methods, and devices for providing multi-zone cooling to a computing device. A cold plate assembly includes a first cooling structure having a coolant inlet and outlet. The first cooling structure is sized, shaped, and configured to interface with (e.g., contact) a first temperature section of the computing device, such as a processor, to provide cooling. For example, the first cooling structure is connected to a first coolant loop that provides a first coolant at a first temperature. Heat can be transferred from the processor, through the first cooling structure, and to the first coolant to be carrier away.

The cold plate assembly includes a second cooling structure, also having an inlet and an outlet. The second cooling structure is sized, shaped, and configured to interface with (e.g., contact) a second temperature section of the computing device, such as one or more memory components, to provide cooling. For example, the second cooling structure is connected to a second coolant loop that provides coolant at a second temperature. Heat can be transferred from the memory components, through the second cooling structure, and to the second coolant to be carrier away.

In this way, the cold plate assembly can provide cooling to separate components of the computing device through independent cooling structures and independent coolant loops. This enables the cold plate to provide cooling through the two structures at different temperatures and/or at different flow rates. For example, the second coolant can be provided at a colder temperature than the first coolant in order to cool the memory components at a lower temperature than the processor, corresponding with the different thermal profiles and cooling needs of these different components. In another example, the first coolant may be provided at a higher flow rate than the second coolant, corresponding with the higher heat generation by the processor in comparison to the memory components. The multi-temperature cooling approach can further be enhanced by a thermal barrier between the two cooling structures to prevent heat transfer and maintain the temperature difference between the two cooling structures. In this way, the cold plate assembly can provide cooling to different components of the computing device that is tailored to the specific needs and requirements of the components in order to increase the effectiveness and efficiency of the cold plate assembly.

Additionally contemplated herein are various systems and configurations for supplying the first and second coolants to the first and second cooling structures (respectively). For example, the coolant systems describe herein may implement one or more server level, rack level, row level, and/or facility level heat exchangers, refrigeration cycles, chillers, fin-fan coolers, and/or any other cooling device or technique for providing coolant to the cold plate assembly at the different temperatures.

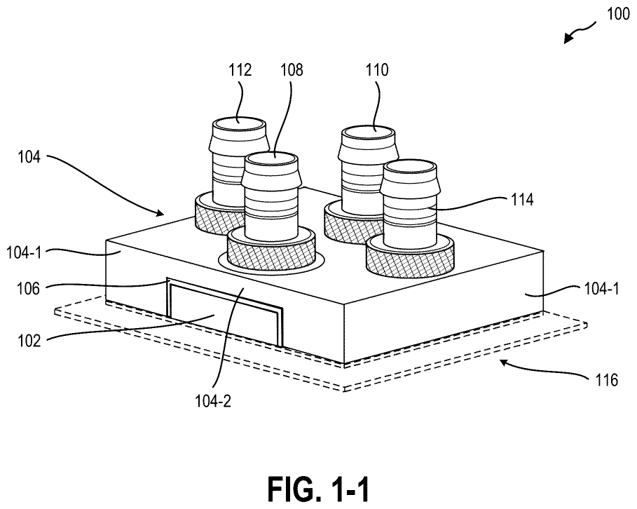

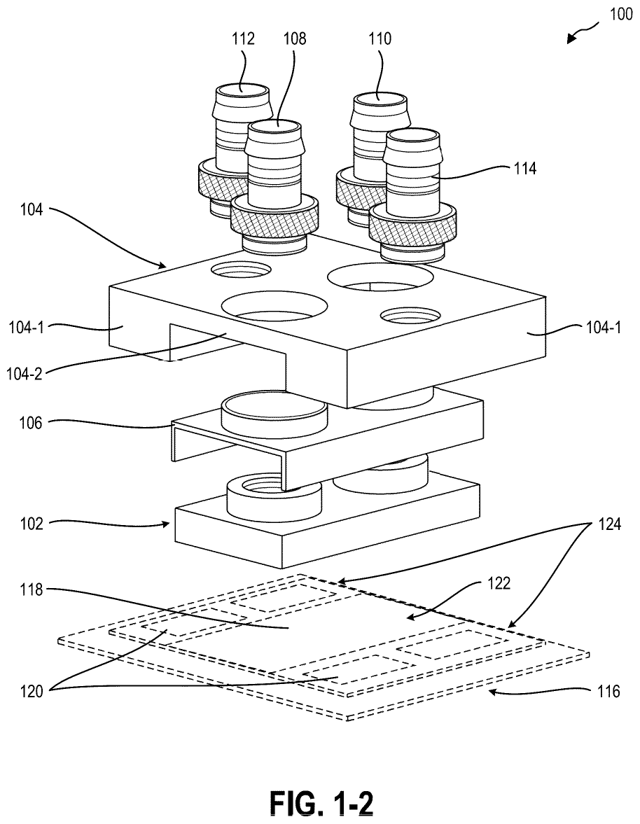

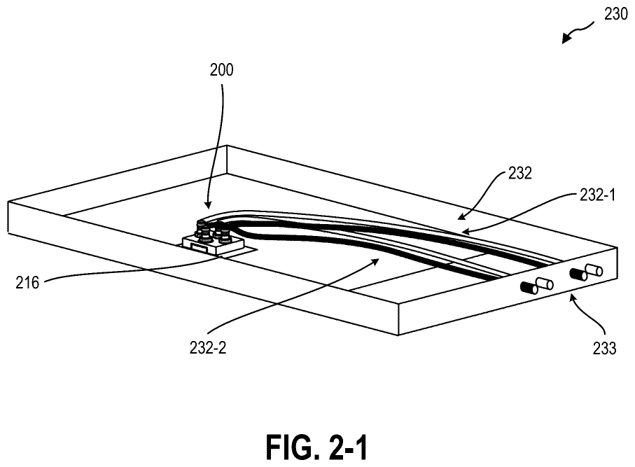

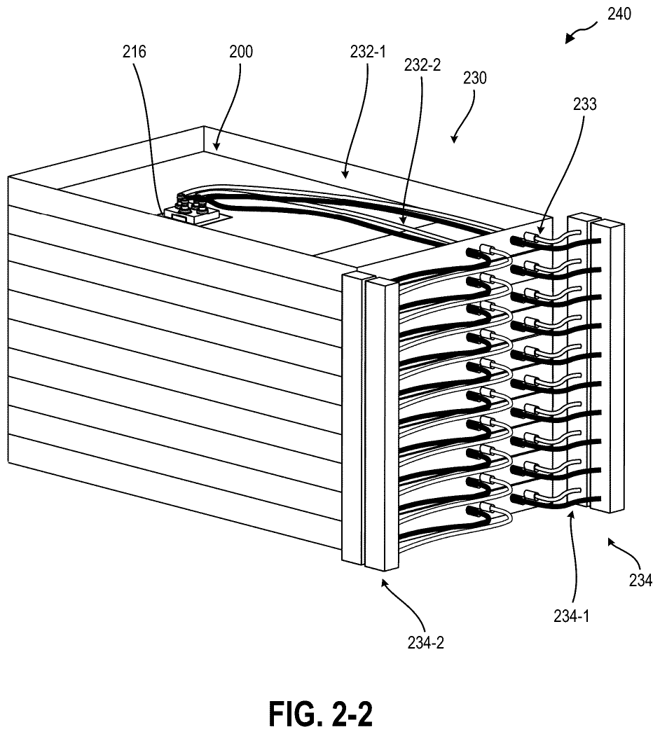

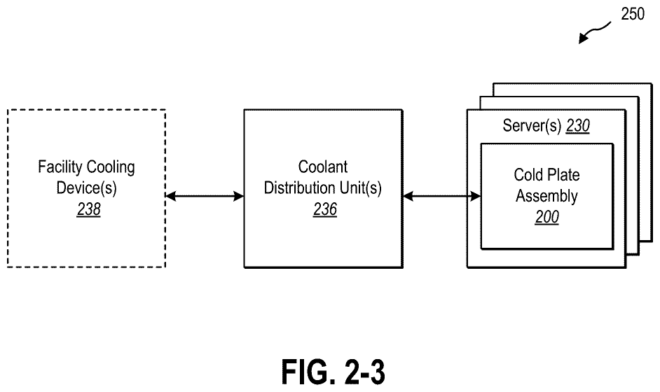

FIG. 1-1 is a perspective view and FIG. 1-2 is an exploded view of a cold plate assembly 100, according to at least one embodiment of the present disclosure.

In some embodiments, the cold plate assembly 100 is configured to provide cooling to a computing device 116. The computing device 116 may include a collection of computing components. For example, the computing device 116 may include processing components (e.g., CPU, GPU, SOC, etc.), memory components (e.g., HBM), input components, output components, or any other computing components, and combinations thereof. In some embodiments, the computing device 116 includes a processing component 118 and at least one memory component 120. The processing component 118 may be centrally positioned with the memory components 120 positioned adjacent and alongside one or more sides of the processing component 118.

In some embodiments, one or more of the computing components have different thermal profiles and/or thermal requirements. For example, the processing component 118 and the memory components 120 may have different operational temperature thresholds, may generate different amounts and/or rates of heat, etc. In some embodiments, the processing component 118 and the memory components 120 have different cooling requirements in accordance with the different thermal profiles. For example, the processing component may operate at a higher temperature than the memory component 120. In some embodiments, the processing component 118 is able to be effectively cooled at higher temperatures and/or with higher temperature coolant. In another example, the processing component 118 may consume more power and may generate more heat, for example, than the memory components 120 (either collectively or individually). A higher rate of heat transfer may accordingly be implemented to cool the processing component 118, such as a higher coolant flow rate. In this way, the computing device 116 may have two or more temperature sections (e.g., a first temperature section 122 and a second temperature section 124), corresponding with the different thermal profiles and/or cooling needs of the various computing components.

In some embodiments, the processing component 118 corresponds with a first temperature section 122 of the computing device 116. For example, the processing component 118 may have a substantially exposed surface area which may facilitate providing efficient cooling to the processing component 118 by transferring (e.g., conducting) heat away over some or all of the surface area. This may allow for cooling of the processing component 118 with warmer coolant temperatures than the memory components 120. In some embodiments, the memory components 120 correspond with a second temperature section 124 of the computing device 116. For example, the memory components 120 may consume less power (e.g., than the processing component 118) and may generate less heat. The memory components 120 may accordingly require a lower rate of heat transfer to cool the memory components 120, such as a lower coolant flow rate. In some embodiments, the memory component 120 are vertically stacked, such as high-bandwidth memory (HBM). Accordingly, a top layer or top memory resource of each memory component 120 may have an exposed surface area for facilitating cooling (e.g., through conductions), but each subsequent layer or memory resource may be at least partially covered by an upper layer. This may prevent one or more lower layers from being effectively cooled through conduction by a cooling device such as a cold plate. In some embodiments, the memory components 120 require cooling (e.g., at an exposed surface area of a top layer) with lower coolant temperatures to ensure adequate cooling is provided to one or more lower layers of the memory components 120.

As shown, the cold plate assembly 100 includes a first cooling structure 102. The first cooling structure 102 may be associated with the first temperature section 122 and/or with the processing component 118. For example, the first cooling structure 102 may be positioned and configured to interface with and provide cooling to the processing component 118. The first cooling structure 102 may be a central or interior portion of the cold plate assembly 100. The first cooling structure 102 may contact some or all of the exposed upper surface area of the processing component 118 and may conduct heat from the processing component 118.

The first cooling structure 102 may include a first coolant inlet 108 and a first coolant outlet 110. The first coolant inlet 108 may receive a flow of a first coolant at a first supply temperature in order to cool the processing component 118. For example, the first cooling structure 102 may have a (at least partially) hollow inner volume. The first coolant may flow in the first coolant inlet 108 at the first supply temperature, and may absorb heat from the first cooling structure 102 as it flows through the first cooling structure 102. The first coolant may then flow out the first coolant outlet 110 at a first return temperature, warmer than the first supply temperature.

In some embodiments, the first cooling structure 102 includes one or more brazed microchannels. The microchannels may direct the flow of the first coolant to more effectively cool the processing component 118. For example, the microchannels may direct the first coolant to spread and flow across the processing component 118. The microchannels may direct the first coolant to flow evenly or uniformly across the processing component 118. The microchannels may direct the first coolant to one or more high heat flux areas of the processing component 118. The microchannels may split the first coolant into one or more flows. The microchannel may direct the split flows evenly and/or in parallel to one or more areas of the processing component 118. The microchannels may direct the split flows unevenly, such as directing more of the first coolant to one or more areas of the processing component 118. The microchannels may be sized and configured to facilitate the flow of the first coolant at a first flow rate (e.g., to achieve a pressure drop threshold of the first cooling structure 102). In this way, the first coolant may absorb and carry away heat from the processing component 118 by flowing through the first cooling structure 102.

As shown, the cold plate assembly 100 includes a second cooling structure 104. The second cooling structure 104 may be associated with the second temperature section 124 and/or with the memory components 120. For example, the second cooling structure 104 may be positioned and configured to interface with and provide cooling to the memory components 120. The second cooling structure 104 may include a peripheral or exterior portion of the cold plate assembly 100. For example, the second cooling structure 104 may include one or more peripheral components 104-1 joined together by a bridge component 104-2. The peripheral components 104-1 may be positioned around the first cooling structure 102, such as alongside one or more (or all) sides of the first cooling structure 102. The quantity and/or positioning of the peripheral components 104-1 may correspond with a quantity and/or positioning of the memory components 120 included in the computing device 116. The bridge component 104-2 may be positioned at least partially above or on top of the first cooling structure 102. In some embodiments, the first cooling structure 102 passes through the bridge component 104-2 at one or more locations (e.g., to facilitate connecting the first coolant inlet 108 and first coolant outlet 110 to the first cooling structure 102). In this way, the first cooling structure 102 may be positioned at least partially within and/or underneath the second cooling structure 104. The second cooling structure 104 may contact some or all of the exposed upper surface (e.g., top layer or top memory resource) of the memory components 120, and may conduct heat from the memory components 120.

The second cooling structure 104 may include a second coolant inlet 112 and a second coolant outlet 114. The second coolant inlet 112 may receive a flow of a second coolant at a second supply temperature in order to cool the memory components 120. For example, the second cooling structure 104 may have a (at least partially) hollow inner volume. The second coolant may flow in the second coolant inlet 112 at the second supply temperature and may absorb heat from the second cooling structure 104 as it flows through the second cooling structure 104. The second coolant may then flow out the second coolant outlet 114 at a second return temperature, warmer than the second supply temperature.

In some embodiments, the second cooling structure 104 includes one or more brazed microchannels. The microchannels of the second cooling structure 104 may exhibit one or more of the features described above in connection with the microchannels of the first cooling structure 102. The microchannels may direct the second coolant through one or more (or all) of the peripheral components 104-1 to facilitate cooling the memory components 120 associated with each peripheral component 104-1. The microchannels may direct the second coolant to flow between the peripheral components 104-1. For example, one or more of the peripheral components may be adjacent and/or may connect at interfacing sides of the peripheral components 104-1, and the second coolant may flow from one peripheral component 104-1 to the next. In some embodiments, peripheral components 104-1 are positioned around all sides of the first cooling structure 102 and/or the first temperatures section 122, and the second coolant may flow in this manner from one peripheral component 104-1 to the next completely around the first cooling structure 102. In some embodiments, the microchannels direct the second coolant to flow through the bridge component 104-2, for example, to flow between the peripheral components 104-1. 104- The microchannels may be sized and configured to facilitate the flow of the second coolant at a second flow rate (e.g., to achieve a pressure drop threshold of the second cooling structure 104). In some embodiments, the microchannels of the second cooling structure 104 have a coarser channel dimension than the microchannels of the first cooling structure 102. In this way, the second coolant may absorb and carry away heat from the memory components 120 by flowing through the second cooling structure 104.

The coolant systems described herein may implement fluids in one or more coolant loops, coolant lines, refrigeration cycles, etc. in accordance with the features and functionalities described herein. The fluids utilized in these capacities (including the first coolant and the second coolant) may include any of water, ethylene glycol, propylene glycol, additives such as organic, inorganic, and/or hybrid coolant additives, dielectric fluids, refrigerants, any other fluid, and combinations thereof. The first coolant and the second coolant may be the same fluid or may be different. In some embodiments, the first and second coolants are glycol.

As mentioned above, the first coolant may be provided at a first supply temperature. In some embodiments, the first supply temperature is 40° C. In some embodiments, the first supply temperature is a value in a range having an upper value, a lower value, or upper and lower values including any of 25° C., 30° C., 35° C., 40° C., 45° C., 50° C., 55° C., 60° C., or any value therebetween. For example, the first supply temperature may be greater than 25° C. In another example, the first supply temperature may be less than 60° C. In yet another example, the first supply temperature may be between 25° C. and 60° C. In some embodiments, it is critical that the first supply temperature be no more than 40° C. to ensure adequate cooling of the processing component 118. For example, the processing component 118 may have a temperature threshold specification (e.g., a case temperature specification) of no more than 40° C., and the first coolant may be provided at or near this temperature in order to maintain the processing component 118 within the temperature threshold.

In some embodiments, the first coolant exits the first cooling structure 102 at the first coolant outlet 110 at a first return temperature. In some embodiments, the first return temperature is 45° C. In some embodiments, the first return temperature is a value in a range having an upper value, a lower value, or upper and lower values including any of 30° C., 35° C., 40° C., 45° C., 50° C., 55° C., 60° C., or 65° C., or any value therebetween. For example, the first return temperature may be greater than 30° C. In another example, the first return temperature may be less than 65° C. In yet another example, the first return temperature may be between 30° C. and 65° C. In some embodiments, it is critical that the first return temperature be no more than 45° C. to ensure that the first coolant can be cooled efficiently and effectively according to the techniques described herein. In some embodiments, it is critical that the change in temperature of the first coolant from the first supply temperature to the first return temperature be no more than 5° C. to ensure that the first coolant can be cooled efficiently and effectively according to the techniques described herein. In some embodiments, it is critical that the first coolant have a first supply temperature of about 40° C. and/or a first return temperature of about 45° C. in order to facilitate implementing the techniques discussed herein. For example, these temperatures may be achieved with dry, or air-cooled equipment in order to efficiently cool the first coolant. In this way, by significant cost and energy savings may be achieved through use of these more efficient cooling means.

As mentioned above, the second coolant may be provided at a second supply temperature. In some embodiments, the second supply temperature is 20° C. In some embodiments, the second supply temperature is a value in a range having an upper value, a lower value, or upper and lower values including any of 5° C., 10° C., 15° C., 20° C., 25° C., 30° C., 35° C., 40° C., or any value therebetween. For example, the second supply temperature may be greater than 5° C. In another example, the second supply temperature may be less than 40° C. In yet another example, the second supply temperature may be between 5° C. and 40° C. In some embodiments, it is critical that the second supply temperature be no more than 20° C. to ensure adequate cooling of the memory components 120. For example, the memory components 120 may have a temperature threshold specification (e.g., a case temperature specification) of no more than 20° C., and the second coolant may be provided at or near this temperature in order to maintain the memory components 120 within the temperature threshold.

In some embodiments, the second coolant exits the second cooling structure 104 at the second coolant outlet 114 at a second return temperature. In some embodiments, the second return temperature is 25° C. In some embodiments, the second return temperature is a value in a range having an upper value, a lower value, or upper and lower values including any of 10° C., 15° C., 20° C., 25° C., 30° C., 35° C., 40° C., 45° C., or any value therebetween. For example, the second return temperature may be greater than 10° C. In another example, the second return temperature may be less than 45° C. In yet another example, the second return temperature may be between 10° C. and 45° C. In some embodiments, it is critical that the second return temperature be no more than 25° C. to ensure that the second coolant can be cooled efficiently and effectively according to the techniques described herein. In some embodiments, it is critical that the change in temperature of the second coolant from the second supply temperature to the second return temperature be no more than 5° C. to ensure that the second coolant can be cooled efficiently and effectively according to the techniques described herein.

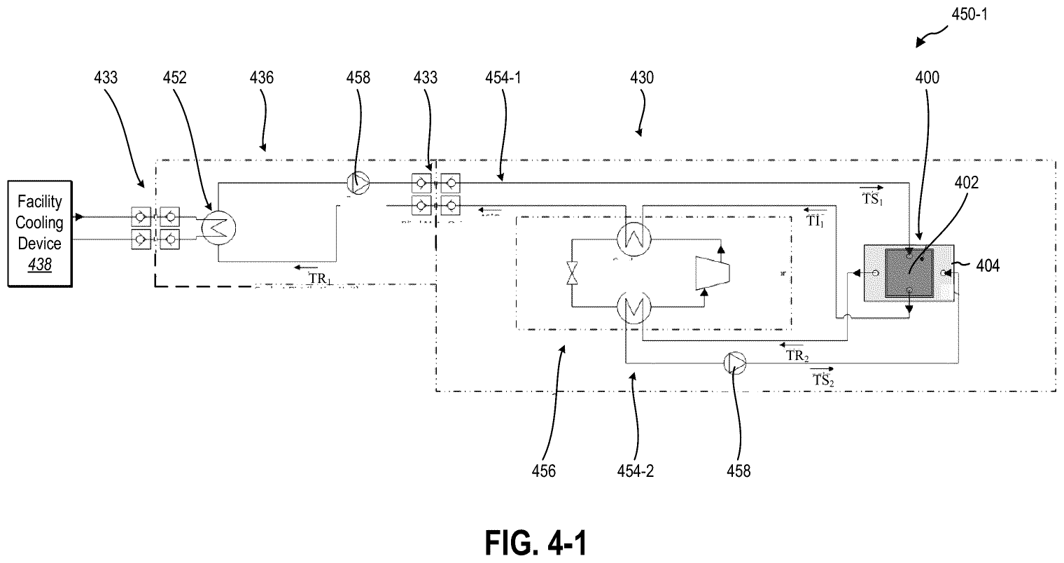

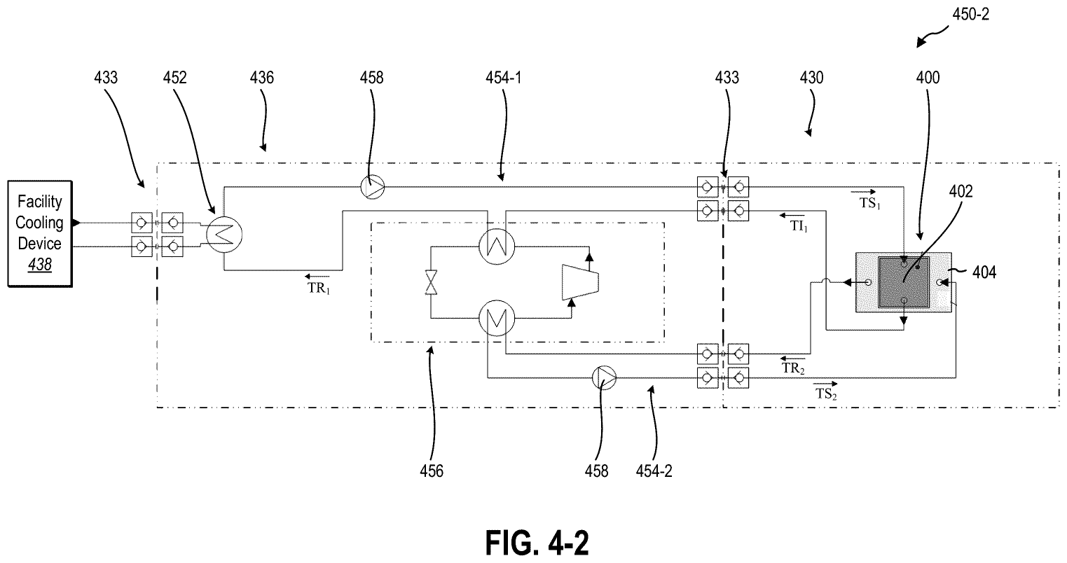

In some embodiments, the second cooling structure 104 provides cooling at a lower temperature than the first cooling structure 102 to facilitate cooling (at least an upper layer of the memory components 120) to a lower temperature than the cooling of the processing component 118, as discussed herein. For example, the second supply temperature may be lower than the first supply temperature. In some embodiments, the second return temperature is lower than the first supply temperature. Various techniques are described herein in connection with FIGS. 3 through 7-2 for providing the first and second coolants at the first and second supply temperatures (respectively).

In some embodiments, the first coolant flows at a first flow rate. The first flow rate may be 1.2 LPM/kW. In some embodiments, the first flow rate is a value in a range having an upper value, a lower value, or upper and lower values including any of 1 LPM/kW, 1.1 LPM/kW, 1.2 LPM/kW, 1.3 LPM/kW, 1.4 LPM/kW, 1.5 LPM/kW, 2 LPM/kW, 3 LPM/kW, or any value therebetween. For example, the first flow rate may be greater than 1 LPM/kW. In another example, the first flow rate may be less than 3 LPM/kW. In yet another example, the first flow rate may be between 1 LPM/kW and 3 LPM/kW. In some embodiments, it is critical that the first flow rate be at least 1.2 LPM/kW to ensure that the heat generated by the processing component 118 may be adequately absorbed and carried away by the first coolant in accordance with the other parameters (e.g., of the first coolant) discussed herein.

In some embodiments, the second coolant flows at a second flow rate. The second flow rate may be 0.5 LPM/kW. In some embodiments, the second flow rate is a value in a range having an upper value, a lower value, or upper and lower values including any of 0.1 LPM/kW, 0.2 LPM/kW, 0.3 LPM/kW, 0.4 LPM/kW, 0.5 LPM/kW, 0.6 LPM/kW, 0.7 LPM/kW, 0.8 LPM/kW, 0.9 LPM/kW, 1 LPM/kW or any value therebetween. For example, the second flow rate may be greater than 0.1 LPM/kW. In another example, the second flow rate may be less than 1 LPM/kW. In yet another example, the second flow rate may be between 0.1 LPM/kW and 1 LPM/kW. In some embodiments, it is critical that the second flow rate be at least 0.5 LPM/kW to ensure that the heat generated by the memory components 120 may be adequately absorbed and carried away by the second coolant in accordance with the other parameters (e.g., of the second coolant) discussed herein.

In some embodiments, it is advantageous to implement the first flow rate of the first coolant and/or the second flow rate of the second coolant in an manner that minimizes the pressure drop across the respective cooling structure, for example, in order to achieve energy savings associated with pumping power.

In some embodiments, the processing component 118 generates more heat and/or may generate heat at a higher rate than the memory components 120. For example, in some embodiments, the processing component 118 produces more than 70% of the heat generated by the computing device 116 (e.g., by consuming more than 70% of the power provided to the computing device 116). Similarly, the memory components 120 may produce less than 30% of the heat generated by the computing device 116 (e.g., by consuming less than 30% of the power provided to the computing device 116). In some embodiments, the second flow rate is less than the first flow rate, for example, in order that heat is transferred from the processing component 118 at this higher quantity and/or higher rate. In some embodiments, the first flow rate is higher than the second flow rate in order to enable cooling of the processing component 118 at higher temperatures (e.g., higher than the cooling of the memory components 120) as discussed herein. In this way, the first cooling structure 102 and second cooling structure 104 may provide cooling distinctly and independently to accommodate the different thermal profiles and temperature thresholds associated with the first temperature section 122 and the second temperature section 124.

As mentioned above, the second cooling structure 104 may contact some or all of the exposed upper surface (e.g., top layer or top memory resource) of the memory components 120, and may conduct heat from the memory components 120. In some embodiments, one or more surfaces of the first cooling structure 102 and of the second cooling structure 104 are coplanar, such as one or more side surfaces, bottom surfaces, top surfaces, any other surfaces, and combinations thereof. This may facilitate including the first cooling structure 102 and second cooling structure 104 in the cold plate assembly 100 as one connected and/or integral unit. For example, in some instances, the processing component 118 and the memory components 120 may have a uniform height and the bottom of the first cooling structure 102 and of the second cooling structure 104 may be coplanar in order to contact the top surface areas of the all of the processing component 118 and memory components 120. This may facilitate a simple and single installation of the cold plate assembly 100.

In some instances, the processing component 118 and memory components 120 may not have a uniform height. For example, some or all of the memory components 120 may extend vertically higher than the processing component 118. In some embodiments, the bottom of the first cooling structure 102 and second cooling structure 104 are not coplanar. For example, the first cooling structure 102 and second cooling structure 104 may be floating with respect to one another (e.g., until the two are connected) in one or more dimensions and/or directions. This may facilitate accommodating differing heights of the processing component 118 and/or memory components 120, as well as accommodating dimensional tolerances of one or more components of the cold plate assembly 100 and/or computing device 116. For example, in some embodiments, the first cooling structure 102 is positioned and connected to the processing component 118 first, and subsequently the second cooling structure 104 is positioned relative to the memory components 120 (e.g., positioned to interface or contact the memory components 120) and then connected or secured to the first cooling structure 102. In some embodiments, the second cooling structure 104 is positioned with respect to the memory components 120 and is additionally or alternatively connected to the memory components 120. In this way, the cold plate assembly 100 may be configured for a maximum or optimal thermal interface between the first cooling structure 102 and the processing component 118 as well as between the second cooling structure 104 and the memory components 120. For example, the separable and/or floating nature of the first cooling structure 102 and the second cooling structure 104 may facilitate increasing an area of surface contact between the respective components of the cold plate assembly 100 and the computing device 116, for example, in situations where the processing component 118 and the memory components 120 do not have a uniform height. In this way, the cold plate assembly 100 may facilitate an effective heat transfer from the computing device 116 despite the computing device 116 having different temperature sections with different thermal requirements.

In some embodiments, the cold plate assembly 100 includes a thermal barrier 106. The thermal barrier 106 may be disposed between the first cooling structure 102 and the second cooling structure 104. The thermal barrier 106 may reduce or prevent heat transfer between the first cooling structure 102 and the second cooling structure 104. For example, as discussed herein, the first cooling structure 102 may provide cooling at, and may operate at, a higher temperature than the second cooling structure 104. Heat from the (e.g., hotter) first cooling structure 102 may have a tendency to transfer to the (e.g., colder) second cooling structure 104 due to the close proximity and/or contact between the two structures. This potential heat transfer may affect the ability of the cold plate assembly 100 to provide the cooling functionalities described herein at the different temperatures. The thermal barrier 106 may be positioned between the first cooling structure 102 and the second cooling structure 104 to prevent heat transfer.

In some embodiments, the thermal barrier 106 is positioned between one or more mating and/or contacting surfaces of the first cooling structure 102 and the second cooling structure 104 (that is, surfaces that would otherwise contact but for the thermal barrier 106). In some embodiments, the thermal barrier 106 is positioned partially between the first cooling structure 102 and the second cooling structure 104 such that the first cooling structure 102 and the second cooling structure 104 contact at one or more locations. In some embodiments, the thermal barrier 106 is positioned completely between the first cooling structure 102 and the second cooling structure 104 such that there is substantially no contact between these two components.

In some embodiments, as shown, the thermal barrier 106 is a separate component from the first cooling structure 102 and the second cooling structure 104. For example, the thermal barrier 106 may include, or may be made of, a material with low thermal conductivity. The thermal barrier 106 may include any plastic, fiberglass, foam, textile, fabric, metal, or any other material for preventing or reducing thermal conductivity between the first cooling structure 102 and the second cooling structure 104, and combinations thereof.

In some embodiments, the thermal barrier 106 is not a separate component from the first cooling structure 102 and the second cooling structure 104, but rather is a structure or feature included in the first cooling structure 102 and/or the second cooling structure 104 at or near a point of contact. For example, the thermal barrier 106 may be implemented as small bumps, ribs, ridges, bridges, or any equivalent structure at a point of contact between the cooling structures. In this way, one or more air gaps may be present between the first cooling structure 102 and the second cooling structure 104 to limit (e.g., conductive) heat transfer. The first cooling structure 102 and the second cooling structure 104 may make a small amount of contact at these bumps, ribs, etc. in order to position these components with respect to one another, but may otherwise not substantially make direct contact other than at the locations of these bumps, ribs, etc. In some embodiments, the thermal barrier 106 may include or may implement a vacuum chamber between some or all interface between the first cooling structure 102 and the second cooling structure 104. In this manner, the thermal barrier 106 may be a mechanical connection for connecting and/or positioning the first cooling structure 102 and the second cooling structure 104 with respect to one another, and may also be a highly thermally resistance mechanical connection which may limit or prevent heat transfer between the first cooling structure 102 and the second cooling structure 104. The thermal barrier 106 as a mechanical connection in this way may exhibit the same thermal conductivity as described above in connection with the thermally resistant material.

In some embodiments, the thermal barrier 106 includes one or more features of both of these implementations. For example, the thermal barrier 106 may include a separate component of a thermally insulating material, and may also include one or more thermally resistant structures at a point of contact of the first cooling structure 102, the second cooling structure 104, and/or the thermal barrier 106. In this way, the thermal barrier 106 may thermally insulate the first cooling structure 102 and the second cooling structure 104 such that little or no heat transfer occurs across the thermal barrier 106, in order to facilitate the multi-zone cooling techniques described herein.

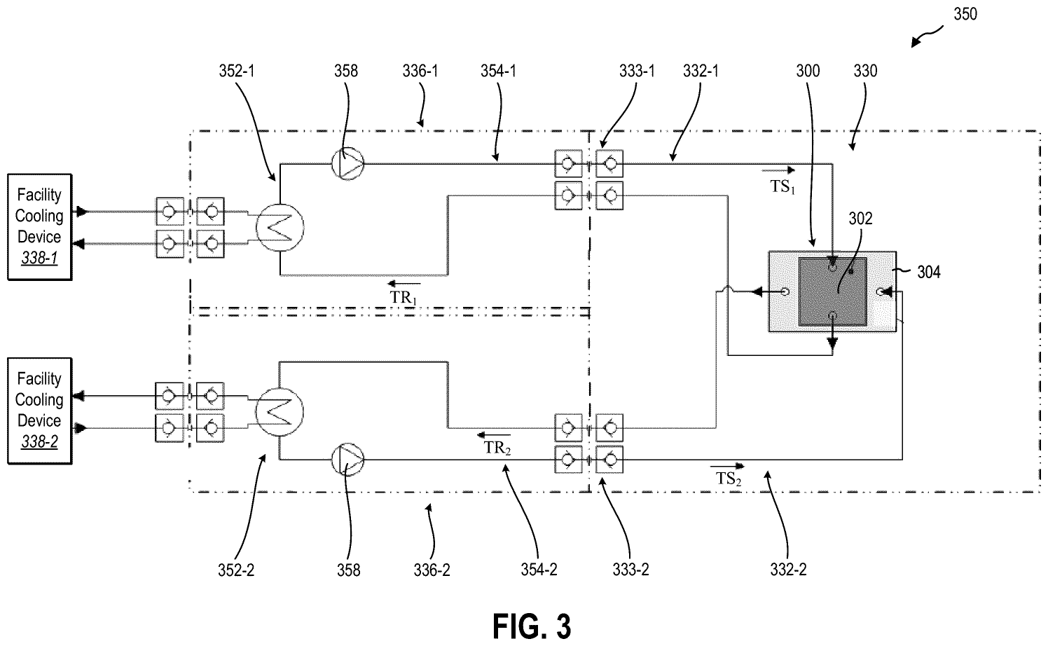

FIG. 2-1 is a perspective view of a server 230 implementing a cold plate assembly 200, according to at least one embodiment of the present disclosure. FIG. 2-2 is a perspective view of a server rack 240 implementing multiple instances of the server 230 of FIG. 2-1. FIG. 2-3 is a diagram illustrating the cold plate assembly 200 connected to a coolant distribution unit 236 as part of a coolant system 250.

The server 230 may include a computing device 216 such as that discussed herein. The cold plate assembly 200 may be implemented in connection with the computing device 216 to cool the computing device 216, and more specifically, to provide multi-zone cooling to different temperature sections of the computing device 216 by way of a first cooling structure and a second cooling structure as discussed herein.

As described herein, the cold plate assembly 200 may be connected to a first coolant loop and a second coolant loop for receiving a first coolant and a second coolant (respectively) at different temperatures and/or flow rates. The server 230 may include a set of first coolant stubs 232-1 and a set of second coolant stubs 232-2 (collectively coolant stubs 232). The first coolant stubs 232-1 may include an inlet stub and an outlet stub and may accordingly connect to a first inlet and a first outlet of the cold plate assembly 200. Similarly, the second coolant stubs 232-2 may include an inlet stub and an outlet stub and may accordingly connect to a second inlet and a second outlet of the cold plate assembly 200. The coolant stubs 232 may facilitate connecting the cold plate assembly 200 into the associated coolant loops and/or into a larger facility coolant system in order to provide the cold plate assembly 200 with the respective coolants at the respective temperatures and/or flow rates. For example, the coolant stubs 232 may terminate at an exterior of the server 230. In some embodiments, the coolant stubs 232 include one or more connections 233 (e.g., quick connects) at the termination to facilitate connecting the server 230 (more specifically the cold plate assembly 200) to a coolant system. For example, as shown in FIG. 2-2 the connections 233 may connect the coolant stubs 232 to one or more coolant manifolds 234. The coolant manifolds 234 may include a first coolant manifold 234-1 and a second coolant manifold 234-2 (corresponding with the first and second coolant loops, coolants, coolant stubs, etc.).

The coolant manifolds 234 may facilitate connecting a plurality of instances of the server 230 in a server rack 240 to the coolant system (e.g., in parallel). For example, a variety of coolant systems for providing the first and second coolants are contemplated and described below. While one or more of these coolant systems may be described with respect to one cold plate assembly 200, or with respect to providing the first and second coolants to one cold plate assembly 200, it should be understood that these coolant systems may be configured to connect to any number of cold plate assemblies 200. The coolant manifolds 234 may facilitate connecting a plurality of servers 230 and cold plate assemblies 200, for example, in parallel in accordance with the described coolant systems. In some embodiments, the coolant manifolds 234 connect to and/or are included in a coolant distribution unit (CDA) 236 for facilitating the widespread implementation of the cooling techniques over many cold plate assemblies 200. In this way, the coolant stubs 232 may connect the server 230 to a coolant system for providing the first and second coolants to the cold plate assembly 200.

As described with respect to one or more of the coolant systems below, in some embodiments a coolant system does not provide both the first coolant and the second coolant (e.g., both warmer and cooler coolants as described herein) to the server 230 from a facility cooling device 238. For example, in some embodiments, a coolant system (e.g., a facility) provides only the first coolant to the server 230, and one or more techniques may be implemented (e.g., within the server 230 and/or the CDU 236) for utilizing the first coolant to also provide the second coolant. Similarly, in some embodiments, a coolant system (e.g., a facility) provides only the second coolant to the server 230, and one or more techniques may be implemented (e.g., within the server 230 and/or the CDU 236) for utilizing the second coolant to also provide the first coolant. In some embodiments, the facility coolant device 238 provides a supply of the second coolant and may receive a return of the first coolant. While FIGS. 2-1 and 2-2 show the server 230 as having two first coolant stubs 232-1 and two second coolant stubs 232-2 each terminating at the connections 233, it should be understood that in embodiments where the coolant system provides less than all of the first coolant and the second coolant, that the server 230 may accordingly include only the associated coolant stubs 232 terminating at the connections 233, and the remaining coolant stubs 232 may accordingly connect to one or more additional components as described herein. In this way, the coolant stubs 232 and connections 233 shown in FIG. 2-2 may be configurable to adapt to any of the coolant systems described below.

As shown in FIG. 2-3, one or more servers 230 may be included in a coolant system 250 by connecting to a CDU 236. The CDU 236 may facilitate providing the first coolant, the second coolant, or both to the cold plate assemblies 200 of the servers 230. For example, as shown, the CDU 236 may connect to one or more facility cooling devices 238. The facility cooling devices 238 may include chillers, cooling towers, dry coolers, fin-fan coolers, or any other suitable cooling device for cooling coolant at a facility level. The CDU 236 may receive one or more of the first coolant and the second coolant having been cooled by the facility cooling devices 238 and may direct the coolant(s) to the servers 230. In some embodiments, the CDU 236 receives one of the first coolant and the second coolant and implements techniques for utilizing that coolant to provide both the first coolant and the second coolant to the servers 230, as described herein. While FIG. 2-3 illustrates one CDU 236 implemented in connection with one or more servers 230, it should be understood that any number of CDUs 236 in combination with any number of servers 230 may be implemented in accordance with the coolant systems described herein. For example, each server 230 may be associated with one CDU 236. In another example, one CDU 236 may be associated with multiple servers 230. In another example, one CDU 236 may be associated with multiple server racks 240 of multiple servers 230 each. In another example, two or more CDUs 236 may be associated with each server 230. Any of the functionalities of the CDU 236 may be performed by one CDU 236 or by multiple CDUs 236, operating independently or in parallel. Indeed, any of the features of the coolant systems described herein may be implemented at a server level, rack level, row level, facility level, or any other level in order to provide the cooling techniques described herein to one or more cold plate assemblies. In this way, the CDU 236 may connect to the servers 230 in order to include the cold plate assemblies 200 in one or more configurations of the coolant system 250.

FIG. 3 is a process diagram of a coolant system 350 according to at least one embodiment of the present disclosure. The coolant system 350 may be implemented in connection with one or more cold plate assemblies 300 as described herein, to provide a first coolant to a first cooling structure 302 of the one or more cold plate assemblies 300 and to provide a second coolant to a second cooling structure 304 of the one or more cold plate assemblies 300. It should be understood that the coolant system 350 may be implemented with respect to any number of CDUs 336 and/or cold plate assemblies 300, for example, connected in parallel, series, or otherwise, as described herein. One or more features or functionalizes of the coolant system 350 may be implemented in connection with any of the coolant systems described herein, or may be implemented individually.

In some embodiments, the cold plate assembly 300 is included in a server 330. A first set of coolant stubs 332-1 may connect the first cooling structure 302 to a first set of connections 333-1 (e.g., quick connects) of the server 330. A second set of coolant stubs 332-2 may connect the second cooling structure 304 to a set of connections 333-2 of the server 330. The first and second set of connections may connect the server 330 to one or more CDUs. These, or similar, connections are shown in one or more of the coolant systems described herein. It should be understood that one or more sets of connections (e.g., quick connects) may be implemented at the locations shown in any of the accompanying figures or at any other location, for facilitating including and/or connecting one or more components to the coolant systems described herein.

In some embodiments, the coolant system 350 includes a first CDU 336-1. The first CDU 336-1 may connect to the first coolant stubs 332-1 and may form a first coolant loop 354-1 for circulating the first coolant to the first cooling structure 302. The first CDU 336-1 may facilitate cooling the first coolant to a first supply temperature TS₁. For example, the first CDU 336-1 may be in thermal communication with a first facility cooling device 338-1 through a first heat exchanger 352-1. The first coolant may flow from the first cooling structure 302 at a first return temperature TR₁, for example, based on the first coolant being used to cool a first temperature section of an associated computing device. The first coolant may flow through the first heat exchanger 352-1 which may cool the first coolant from a first return temperature TR₁ to the first supply temperature TS₁. In some embodiments a pump 358 is implemented in connection with the first coolant loop 354-1 (e.g., in the first CDU 336-1) to circulate the first coolant. In this way, the coolant system 350 may provide a flow of the first coolant to the first cooling structure 302 of the cold plate assembly 300.

In some embodiments, the coolant system 350 includes a second CDU 336-2. The second CDU 336-2 may connect to the second coolant stubs 332-2 and may form a second coolant loop 354-2 for circulating the second coolant to the second cooling structure TS₂. The second CDU 336-2 may facilitate cooling the second coolant to a second supply temperature TS₂. For example, the second CDU 336-2 may be in thermal communication with a second facility cooling device 338-2 through a second heat exchanger 352-2. The second coolant may flow from the second cooling structure 304 at a second return temperature TR₂, for example, based on the second coolant being used to cool a second temperature section of an associated computing device. The second coolant may flow through the second heat exchanger 352-2 which may cool the second coolant from a second return temperature TR₂ to the second supply temperature TS₂. In some embodiments a pump 358 is implemented in connection with the second coolant loop 354-2 (e.g., in the second CDU 336-2) to circulate the second coolant. In this way, the coolant system 350 may provide a flow of the second coolant to the second cooling structure 304 of the cold plate assembly 300.

The coolant system 350 providing two separate and independent coolant loops for circulating two different coolants may facilitate providing a more effective cooling for the respective temperature sections of the computing device. For example, as described herein, a first temperature section of the computing device (e.g., a processor) may generate more heat than a second temperature section (e.g., memory). The first coolant may accordingly be implemented at a higher flow rate to dissipate more heat from the first temperature section. As another example, and as described herein, the second temperature section may be cooled at lower temperatures than the first temperature section. The second supply temperature TS₂ of the second coolant may accordingly be lower the first supply temperature TS₁ of the first coolant. Having the two separate coolant loops may facilitate implementing two separate facility cooling devices in order to provide the first and second coolants with these respective properties in order to tailor a more effective cooling of each temperature section.

The independent nature of the coolant loops in this way may also provide efficiency benefits. For example, faculty cooling devices (e.g., facility cooling devices 338-2) such as chillers, cooling towers, and the like may be needed, in some cases, to cool the second coolant to these lower temperatures. These facility cooling devices may be less energy efficient than coolers such as dry coolers, fin-fan coolers, and the like (e.g., facility cooling device 338-1), which may be implemented to cool the first coolant to the warmer coolant temperatures. Should only one coolant used in with the cold plate assembly 300, or should one type of facility cooling device be used to provide both coolants, the coolant would have to be provided at the most restrictive temperature (that of the second coolant) and would have to be provided by a facility cooling device such as a chiller. By separating these two coolants, however, the more energy consuming facility cooling devices (e.g., chillers) may be implemented only where needed for the second coolant, and the more energy efficient cooling devices (e.g., fin-fan cooler) may be implemented to provide the first coolant, achieving significant energy savings. This is especially apparent when considering that the first temperature section may represent as much as 70% or more of the total heat generation of the computing device. Thus, up to 70% or more of the cooling of the computing device may be achieved with the more energy efficient first coolant.

FIGS. 4-1 and 4-2 are process diagrams of coolant systems 450-1 and 450-2 (respectively) each implementing a heat pump 456. The coolant systems 450-1 and 450-2 may be implemented in connection with one or more cold plate assemblies 400 as described herein, to provide a first coolant to a first cooling structure 402 of the one or more cold plate assemblies 400 and to provide a second coolant to a second cooling structure 404 of the one or more cold plate assemblies 400. It should be understood that the coolant system 450-1 and 450-2 may be implemented with respect to any number of CDUs 436 and/or cold plate assemblies 400, for example, connected in parallel, series, or otherwise, as described herein. One or more features or functionalities of the coolant systems 450-1 and 450-2 may be implemented in connection with any of the coolant systems described herein, or may be implemented individually. The coolant systems 450-1 and 450-2 may be referred collectively as coolant systems 450.

The coolant systems 450-1 and 450-2 may have similar configurations and may operate based on similar principles. For example, the coolant systems 450-1 and 450-2 may each include a first coolant loop 454-1 cooled by a facility cooling device 338 to a first supply temperature TS₁, and may implement a heat pump 456 to cool a second coolant loop to a second supply temperature TS₂. Coolant system 450-1 may implement the heat pump 456 within (or associated with) a server 430, and may only receive the first coolant from a CDU 436. Coolant system 450-2 may implement the heat pump 456 within (or associated with) the CDU 436, and the server 430 may receive both the first and second coolants from the CDU 436. The coolant systems 450 may each include one or more sets of connections 433 for connecting the server 430, the CDU 436, and/or any other component to the coolant systems 450. The coolant systems 450 may each include one or more pumps 458 for circulating one or more coolants. The pumps 458 shown (or any additional pumps 458) may be located as shown and/or may be located at any other location in the coolant systems 450 for circulating the coolants.

The first coolant loop 454-1 may be in thermal communication with a facility cooling device 438 for cooling the first coolant through a heat exchanger 452. For example, the heat exchanger 452 may cool the first coolant from a first return temperature TR₁ to the first supply temperature TS₁. The first coolant loop 454-1 may connect to the first cooling structure 402 for cooling a first temperature section of a computing device with the first coolant, as described herein.

As mentioned above, the coolant systems 450-1 may include a heat pump 456. The heat pump 456 may be in thermal communication with the first coolant loop 454-1 and a second coolant loop 454-2. For example, the heat pump 456 may include one or more of a compressor, condenser, expansion valve, and evaporator for implementing a refrigeration cycle to reject heat from the second coolant loop 454-2 to the first coolant loop 454-1. In this way, a second coolant may be cooled from a second return temperature TR₂ to the second supply temperature TS₂. The second coolant loop 454-2 may connect to the second cooling structure 404 for cooling a second temperature section of the computing device.

In some embodiments, the temperature at which the first coolant exits the first cooling structure 402 is a first intermediate temperature TI₁. In some embodiments, the first intermediate temperature TI₁ is not the same as the first return temperature TR₁ (e.g., the temperature at which the first coolant is returned to the heat exchanger 452). For example, the first coolant may flow to the heat pump 456 at the first intermediate temperature TI₁. The heat pump 456 may reject heat from the second coolant to the first coolant which may raise the temperature of the first coolant from the first intermediate temperature TI₁ to the first return temperature TR₁. In some embodiments, the difference between the first intermediate temperature TI₁ and the first return temperature TR₁ is between 1° C. and 5° C.

In this way, the heat that is dissipated and/or carried away from the second temperature section of the computing device by the second coolant may be transferred to the first coolant, and the first coolant may effectively carry away all of the heat generated by the computing device, to be cooled by the facility cooling device 438 at the heat exchanger 452. The coolant systems 450 in this way may facilitate providing the first and second coolants at their respective temperatures while only providing cooling at the facility level of the first, warmer, coolant. As mentioned, the first coolant may be cooled by utilizing more energy efficient techniques such dry, fin-fan coolers. In contrast to the coolant system 350 describe in connection with FIG. 3, the coolant systems 450 may cool the second coolant without implementing less energy-efficient facility cooling devices such as chillers. In some embodiments, operating the heat pump 456 (or multiple heat pumps 456 in the aggregate of many computing devices) is more energy efficient than operation of a facility-wide chiller. In this way, the coolant systems 450 may provide energy savings while still providing the increased effectiveness of the multi-zone cooling through the first and second coolants.

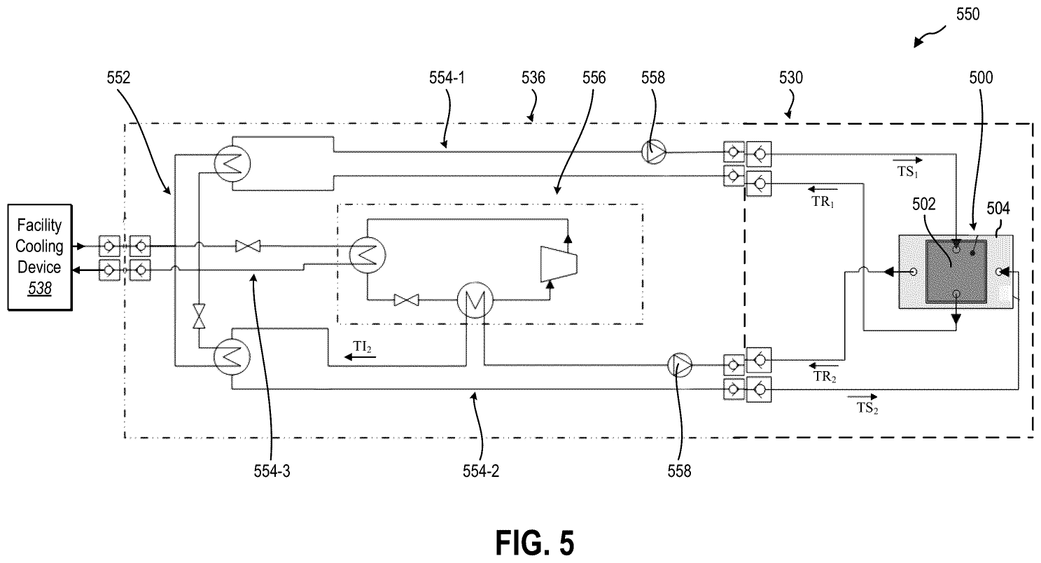

FIG. 5 is a process diagram of a coolant system 550 implementing a heat pump 556, according to at least one embodiment of the present disclosure. The coolant system 550 may be implemented in connection with one or more cold plate assemblies 500 as described herein, to provide a first coolant to a first cooling structure 502 of the one or more cold plate assemblies 500 and to provide a second coolant to a second cooling structure 504 of the one or more cold plate assemblies 500. The coolant system 550 may include and may be implemented across one or more servers 530 and one or more CDUs 536. It should be understood that the coolant system 550 may be implemented with respect to any number of CDUs 536 and/or cold plate assemblies 500, for example, connected in parallel, series, or otherwise, as described herein. One or more features or functionalities of the coolant system 550 may be implemented in connection with any of the coolant systems described herein, or may be implemented individually. Additionally, it should be understood that the coolant system 550 is not limited to the embodiment shown in FIG. 5, but that one or more features or functionalities shown and described as relating specifically to the server 530 or the CDU 536 may be implemented as part of the server 530, the CDU 536, or both.

The coolant system 550 may include a first coolant loop 554-1 for circulating the first coolant to the first cooling structure 502. The coolant system 550 may include a second coolant loop 554-2 for circulating the second coolant to the second cooling structure 504. The coolant system 550 may include one or more pumps 558 at the shown locations (or any other locations) for circulating the first and second coolants.

As mentioned above, the coolant system 550 includes a heat pump 556. The heat pump 556 may be in thermal communication with the second coolant loop 554-2 for cooling the second coolant. The heat pump 556 may additionally be in thermal communication with a facility cooling device 538 (e.g., a facility coolant loop 554-3 of the facility cooling device 538) for rejecting heat from the second coolant loop to the facility coolant loop 554-3. For example, the second coolant may flow to the heat pump 556 at a second return temperature TR₂ and the heat pump may cool the second coolant to a second supply temperature TS₂ (or second intermediate temperature TI₂ as described below). In this way, the facility cooling device 538 may be utilized to cool the second coolant loop through the heat pump 556.

In some embodiments, the facility cooling device 538 is a more energy-efficient facility cooling device, such as a fin-fan cooler. As described herein, this type of facility cooling device may be capable of providing cooling for the first, warmer coolant, but in some cases may not be suitable for providing cooling at the colder temperatures of the second coolant. However, in some cases, such as on a cold day, a fin-fan cooler (or equivalent) may be able to provide cooling at lower temperatures, such as closer to that needed for the second coolant. In such cases, this more energy-efficient type of facility cooling device may be implemented to cool the second coolant, through the use of the heat pump 556. For example, the heat pump 556 may include one or more of a compressor, condenser, expansion valve, and evaporator for implementing a refrigeration cycle to reject heat from the second coolant loop 454-2 to the facility coolant loop 554-3. In some embodiments, the heat pump 556 does not implement the refrigeration cycle, but facilitates heat transfer directly from the second coolant loop 554-2 to the facility coolant loop 554-3 (e.g., if the weather conditions are such that the facility cooling device 538 can cool to a sufficient temperature).

As described herein, the first coolant may be supplied to the first cooling structure 502 at a first supply temperature TS₁ and may exit the first cooling structure at a first return temperature TR₁. Similarly, the second coolant may be supplied to the second cooling structure at the second supply temperature TS₂ and may exit the second cooling structure at the second return temperature TR₂. In some embodiments, the coolant system 550 utilizes the cooling of the second coolant loop 554-2 to cool the first coolant loop 554-1. For example, the coolant system 550 may include a heat exchanger 552 in thermal communication with the first coolant loop 554-1 and the second coolant loop 554-2 to reject heat from the first coolant loop 554-1 to the second coolant loop 554-2. In some embodiments, the second coolant flows to the heat pump 556 at the second return temperature TR₂, and the heat pump 556 cools the second coolant to a second intermediate temperature TI₂ lower than the second supply temperature TS₂ (e.g., the temperature at which the second coolant flows into the second cooling structure 504). The second coolant may then flow to the heat exchanger 552 at the second intermediate temperature TI₂ where the temperature may increase to the second supply temperature TS₂. This may be a result of heat being transferred from the first coolant to the second coolant in the heat exchanger 552 in order to cool the first coolant from the first return temperature TR₁ to the first supply temperature TS₁.

In this way, the coolant system 550 may provide both the first, warmer, coolant and the second, colder, coolant to the cold plate assembly 500, by cooling the second coolant directly (e.g., through the heat pump 556) with a more energy-efficient, and typically higher temperature, facility cooling device 538, such as a dry fin-fan cooler. The coolant system 550 in this way may be an economizer coolant system that may be implemented or activated to provide more energy efficient cooling of the second coolant, for example, when weather conditions permit such an application.

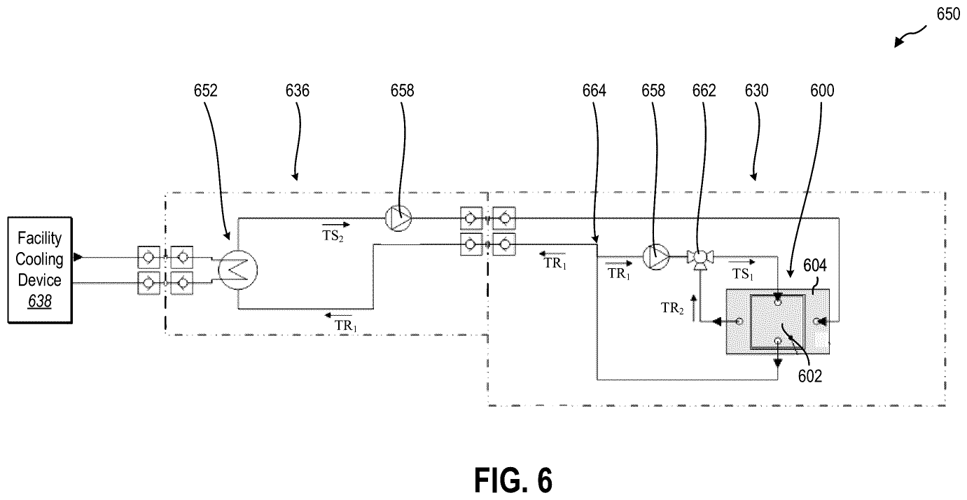

FIG. 6 is a process diagram of a coolant system 650, according to at least one embodiment of the present disclosure. The coolant system 650 may be implemented in connection with one or more cold plate assemblies 600 as described herein, to provide a coolant at a first supply temperature TS₁ to a first cooling structure 602 of the one or more cold plate assemblies 600 and to provide the coolant at a second supply temperature TS₂ to a second cooling structure 604 of the one or more cold plate assemblies 600. The coolant system 650 may include and may be implemented across one or more servers 630 and one or more CDUs 636. It should be understood that the coolant system 650 may be implemented with respect to any number of CDUs 636 and/or cold plate assemblies 600, for example, connected in parallel, series, or otherwise, as described herein. One or more features or functionalizes of the coolant system 650 may be implemented in connection with any of the coolant systems described herein, or may be implemented individually. Additionally, it should be understood that the coolant system 650 is not limited to the embodiment shown in FIG. 6, but that one or more features or functionalities shown and described as relating specifically to the server 630 or the CDU 636 may be implemented as part of the server 630, the CDU 636, or both.

The coolant system 650 may circulate a single coolant (e.g., in contrast to the first and second coolants described in one or more embodiments herein). The coolant system 650 may implement one or more techniques for supplying the coolant to the first cooling structure at the first supply temperature TS₁ and to the second cooling structure at the second supply temperature TS₂.

The coolant system 650 may include a facility cooling device 638 for cooling the coolant to the second supply temperature TS₂ via a heat exchanger 652. The facility cooling device 638 may be a chiller or equivalent device for cooling the coolant to the lower, second supply temperature TS₂. The coolant may flow from the heat exchanger 652 (e.g., via a pump 658) at the second supply temperature TS₂ to the second cooling structure 604. The coolant may exit the second cooling structure at a second return temperature TR₂.

In some embodiments, the second return temperature TR₂ is a lower temperature than the first supply temperature TS₁. In some embodiments, the coolant system 650 utilizes this lower return temperature of the second coolant to cool the supply of the first coolant. For example, the coolant system 650 may include a mixing valve 662. The mixing value may be in fluid communication with a first return line from the first cooling structure 502 and a second return line from the second cooling structure 504. In this way, the mixing valve may receive (at least some of) the coolant from the first return at the first return temperature TR₁, and may receive the coolant from the second return at the second return temperature TR₂. The mixing valve 662 may mix the coolant from the first return and the second return to form a resulting coolant that is at the first supply temperature TS₁. This resulting coolant may then be supplied to the first cooling structure to facilitate the cooling functionalities described herein.

The mixing valve 662 may receive less than all of coolant from the first return for mixing with the coolant from the second return. For example, the coolant system 650 may include a splitter 664 for splitting a flow of the first return such that a portion of the coolant flows to the mixing valve, and the remainder flows to the heat exchanger 652 to be cooled to the second supply temperature TS₂. In some embodiments, a pump 658 draws a portion of the coolant from the first return to be mixed at the mixing valve 662. Additionally, as described herein, the coolant provided to the first cooling structure 602 may be at a higher flow rate than that provided to the second cooling structure 604. By mixing all of the coolant from the second return with some of the coolant from the first return, the flow from the second cooling structure 604 may be augmented to achieve the higher flow rates for the first cooling structure 602.

In this way, a single coolant may be provided (e.g., at a facility level) at a single temperature, and the coolant system 650 may provide the coolant to both the first cooling structure 602 and the second cooling structure 604 at the distinct associated temperatures. By only operating one (e.g., one type of) facility cooling device 638, the coolant system 650 may provide energy efficiency benefits over other embodiments, for example, implementing separate facility cooling device 638 to provide separate coolants at separate temperatures.

The coolant systems described herein in connection with FIGS. 3-6 may be implemented in connection with the multi-zone cold plate assembly to achieve a more energy-efficient cooling of one or more computing devices. For example, as described, by isolating cooling to specific zones and tailoring the cooling to the specific needs of those zones, less energy may be wasted in cooling one or more computing components (e.g., a processor) more than needed. In some embodiments, energy savings are achieved by utilizing less energy-efficient cooling devices (e.g., chillers) only where needed (and on a smaller scale) for the lower temperature coolants, and by utilizing more energy efficient facility cooling devices (e.g., fin-fan coolers) for the higher temperature coolants. In other embodiments, energy savings are achieved by utilizing the more energy efficient facility cooling devices for providing both the higher and lower temperature coolants through various techniques. In still other embodiments, energy savings are achieved by providing facility cooling for the lower temperature coolant only, but utilizing that lower temperature coolant (e.g., after it is used in the cold plate assembly) to further cool the higher temperature coolant. The various energy savings from the coolant systems describe herein may provide significant cost savings when implemented in the aggregate over a large scale data center having hundreds, thousands, or more cold plate assemblies.

Additionally, one or more of the coolant systems described herein may facilitate a logistically simple implementation in a data center, including retrofitting an existing data center with the cold plate assembly described herein. For example, many data centers already utilized facility level coolants to cool various components of the data center. Coolant systems described herein that utilize only one type of facility level cooling (e.g., higher temperature or lower temperature cooling) may be more easily implemented in data centers that already offer that type (e.g., temperature) of cooling. Thus, the cold plate assembly, which requires coolants of varying temperatures, may be easily implemented in data centers using one or more of the disclosed coolant systems (and variations thereof). Indeed, the cold plate assembly may be implemented in connection with other types or generations of cold plates and cooling assemblies without having to substantially change the existing infrastructure of a datacenter.

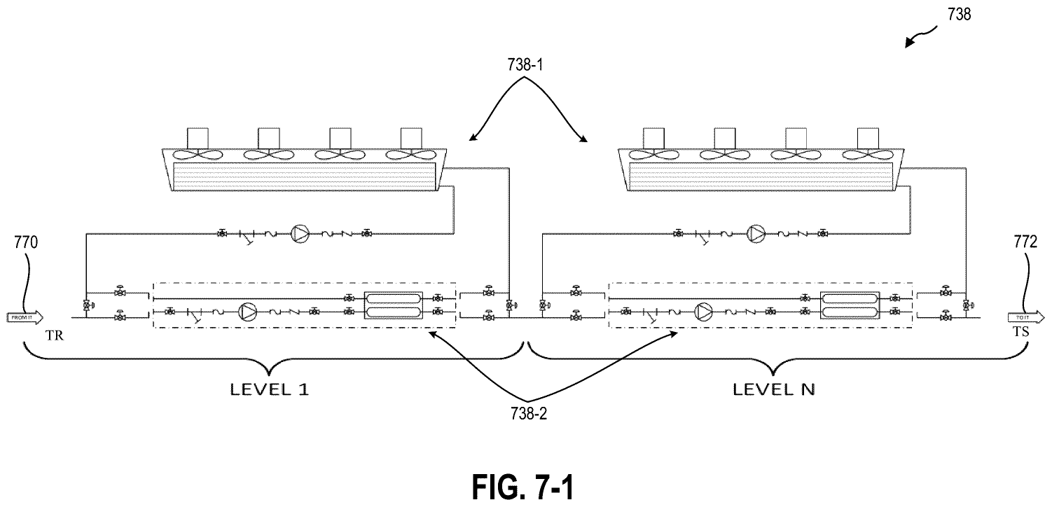

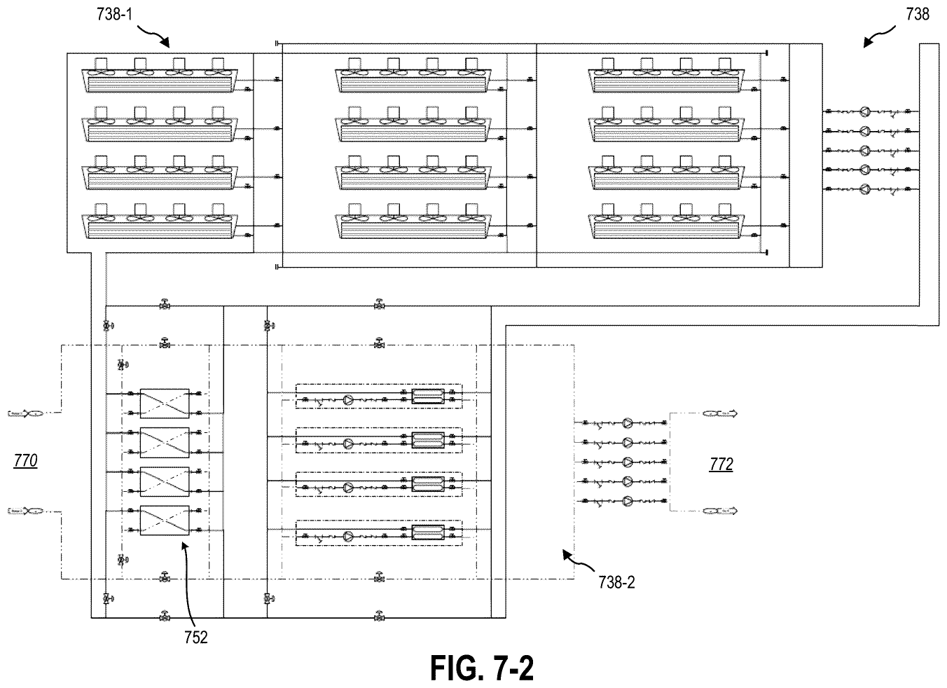

FIG. 7-1 is a process diagram of one or more facility level cooling devices 738 as described herein, according to at least one embodiment of the present disclosure. The facility level cooling devices 738 may be implemented with one or more of the coolant systems described herein in connection with FIGS. 3-6.

The facility level cooling devices 738 may receive a flow of coolant at a return temperature TR from a return 770. The facility level cooling devices 738 may process the coolant and may produce the coolant at a supply temperature TS at a supply 772. The facility level cooling devices 738 may include one or more first cooling devices 738-1. The first cooling devices 738-1 may be a more energy-efficient type of cooling device such as a dry cooler or a fin-fan cooler. The first cooling devices 738-1 may also be more limited in their ability to cool the coolant to lower temperatures. The facility level cooling devices 738 may include one or more second cooling devices 738-2. The second cooling devices 738-2 may be a less energy-efficient type of cooling devices such a chiller. The second cooling devices 738-2 may be more capable for cooling the coolant to lower temperatures.

In some embodiments, one or more facility level cooling devices 738 include one or more first cooling devices 738-1 and one or more second cooling devices 738-2 as shown. Any combination and/or configuration of the first cooling devices 738-1 and second cooling device 738-2 may be implemented, including bypassing one or more components, in order to cool the coolant to the supply temperature TS.

In some embodiments, the coolant flows from the return 770 to the first cooling device 738-1. In some embodiments, the first cooling device 738-1 cools the coolant to the supply temperature TS and the coolant bypass one or more additional cooling devices and flow to the supply 772. In some embodiments, the coolant is cooled to the supply temperature TS by passing through a series of cascading or tiered first cooling devices 738-1, after which the coolant flows to the supply 772. In some embodiments, the coolant is precooled by the first cooling devices 738-1. For example, the coolant may be cooled to a temperature higher than the supply temperature TS by one or more (e.g., cascading) first cooling devices 738, after which the coolant may pass to one of the second cooling devices 738-2, where it may be cooled the rest of the way to the supply temperature TS. In some embodiments, the coolant passes through a series of cascading or tiered second cooling devices 738-2 after being precooled in order that the coolant is cooled to the supply temperature TS. In some embodiments, the coolant flows from the return 770 and does not flow to the first cooling devices 738-1, but is cooled to the supply temperature TS entirely by one or more of the second cooling devices 738-2. For example, the coolant may be cooled by the second cooling devices 738-2 which may reject heat (via a hot side) to the first cooling devices 738-1. In this way, facility level cooling may be provided for one or more coolants in accordance with any of the coolant systems described herein.

FIG. 7-2 is a process diagram illustrating a large-scale implementation of the facility level cooling devices 738 of FIG. 7-1 as described herein, according to at least one embodiment of the present disclosure. As shown, multiple of the various cooling devices of FIG. 7-1 are shown (e.g., in parallel) for achieving the features and functionalities described in connection with FIG. 7-1 at a facility level. For example, a coolant may flow from the return 770 to the supply 772 and may be cooled through any of a variety of combinations of the first cooling devices 738-1 (via heat exchangers 752) and the second cooling devices 738-2.

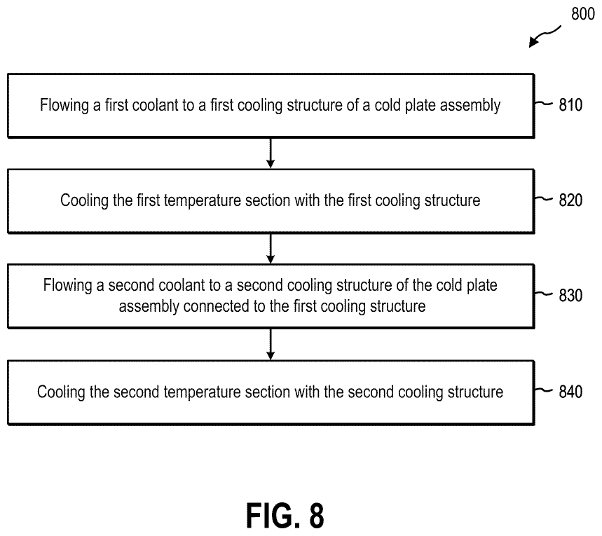

FIG. 8 illustrates a flow diagram for a method 800 or a series of acts for cooling a computing device having a first temperature section and a second temperature section as described herein, according to at least one embodiment of the present disclosure. While FIG. 8 illustrates acts according to one embodiment, alternative embodiments may omit, add to, reorder, or modify any of the acts shown in FIG. 8.

In some embodiments, the method 800 includes an act 810 of flowing a first coolant to a first cooling structure of a cold plate assembly.

In some embodiments, the method 800 includes an act 820 of cooling the first temperature section with the first cooling structure.

In some embodiments, the method 800 includes an act 830 of flowing a second coolant to a second cooling structure of a cold plate assembly connected to the first cooling structure. In some embodiments, a thermal barrier is positioned between the first cooling structure and the second cooling structure to prevent thermal conduction between the first cooling structure and the second cooling structure.

In some embodiments, the method 800 includes an act 840 of cooling the second temperature section with the second cooling structure. The second temperature section may be cooled at a lower temperate than the first temperature section. For example, the first temperature section may have a higher temperature threshold than the second temperature section. In some embodiments, the second coolant is flowed to the second cooling structure at a lower temperature than a temperature at which the first coolant is flowed to the first cooling structure. In some embodiments, the first coolant is flowed at a higher flow rate than the second coolant.

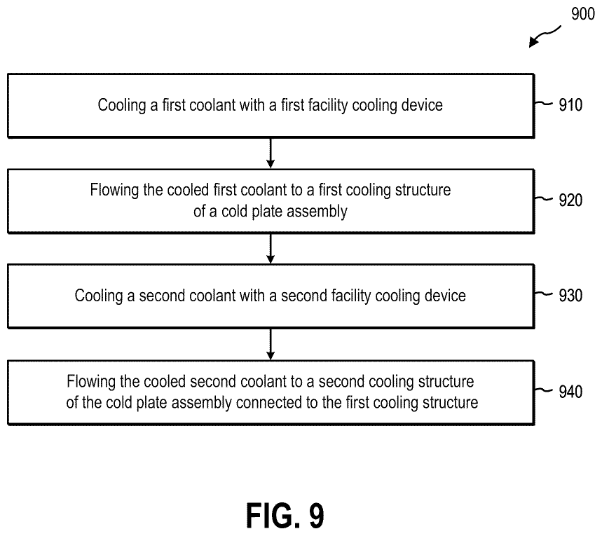

FIG. 9 illustrates a flow diagram for a method 900 or a series of acts for cooling a computing device as described herein, according to at least one embodiment of the present disclosure. While FIG. 9 illustrates acts according to one embodiment, alternative embodiments may omit, add to, reorder, or modify any of the acts shown in FIG. 9.

In some embodiments, the method 900 includes an act 910 of cooling a first coolant with a first facility cooling device.

In some embodiments, the method 900 includes an act 920 of flowing the cooled first coolant to a first cooling structure of a cold plate assembly. In some embodiments, the first cooling structure cools a first temperature section of the computing device based on flowing the cooled first coolant to the first cooling structure. In some embodiments, the first coolant is flowed in parallel to a plurality of first cooling structures of a plurality of cold plate assemblies.

In some embodiments, the method 900 includes an act 930 of cooling a second coolant with a second facility cooling device. For example, the second coolant may be cooled to a lower temperature than the first coolant.

In some embodiments, the method 900 includes an act 940 of flowing the cooled second coolant to a second cooling structure of a cold plate assembly connected to the first cooling structure. In some embodiments, the second cooling structure cools a second temperature section of the computing device based on flowing the cooled second coolant to the second cooling structure. In some embodiments, the first coolant is flowed at a higher flow rate than the second coolant. In some embodiments, the second coolant is flowed in parallel to a plurality of second cooling structures of a plurality of cold plate assemblies.

In some embodiments, the method 900 corresponds with the coolant system 350 described herein in connection with FIG. 3. The method 900 may apply to any other coolant system.

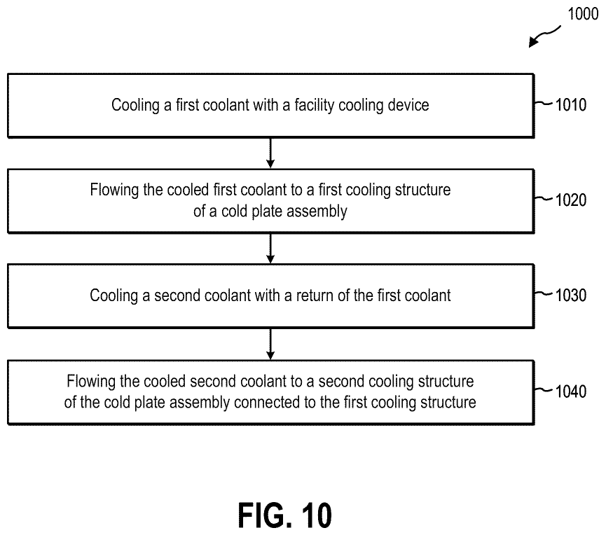

FIG. 10 illustrates a flow diagram for a method 1000 or a series of acts for cooling a computing device having a first temperature section and a second temperature section as described herein, according to at least one embodiment of the present disclosure. While FIG. 10 illustrates acts according to one embodiment, alternative embodiments may omit, add to, reorder, or modify any of the acts shown in FIG. 10.

In some embodiments, the method 1000 includes an act 1010 of cooling a first coolant with a facility cooling device.

In some embodiments, the method 1000 includes an act 1020 of flowing the cooled first coolant to a first cooling structure of a cold plate assembly. In some embodiments, the first cooling structure cools a first temperature section of the computing device based on flowing the cooled first coolant to the first cooling structure. In some embodiments, the cooled first coolant is flowed in parallel to a plurality of first cooling structures of a plurality of cold plate assemblies.

In some embodiments, the method 1000 includes an act 1030 of cooling a second coolant with a return of the first coolant. In some embodiments, the return of the first coolant is a higher temperature than the second coolant. In some embodiments, the second coolant is cooled by rejecting heat from the second coolant to the return of the first coolant with a heat pump.

In some embodiments, the method 1000 includes an act 1040 of flowing the cooled second coolant to a second cooling structure of the cold plate assembly connected to the first cooling structure. In some embodiments, the second cooling structure cools a second temperature section of the computing device based on flowing the cooled second coolant to the second cooling structure. In some embodiments, the cooled second coolant is flowed in parallel to a plurality second cooling structures of a plurality of cold plate assemblies.

In some embodiments, the method 1000 corresponds with the coolant systems 450-1 and/or 450-2 described herein in connection with FIGS. 4-1 and 4-2. The method 1000 may apply to any other coolant system.

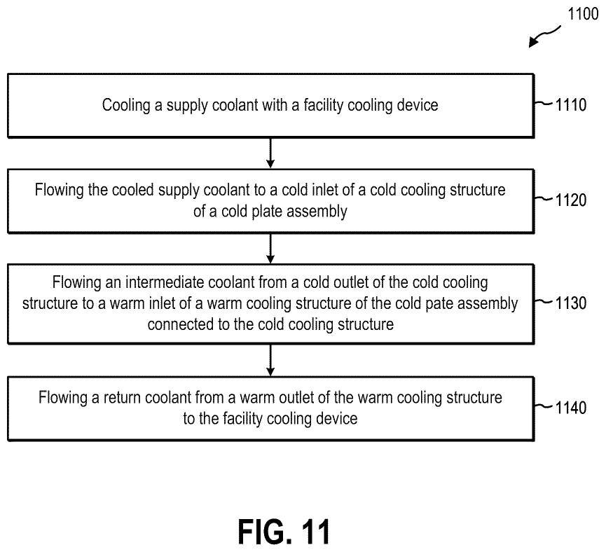

FIG. 11 illustrates a flow diagram for a method 1100 or a series of acts for cooling a computing device having a first temperature section and a second temperature section as described herein, according to at least one embodiment of the present disclosure. While FIG. 11 illustrates acts according to one embodiment, alternative embodiments may omit, add to, reorder, or modify any of the acts shown in FIG. 11.

In some embodiments, the method 1100 includes an act 1110 of cooling a supply coolant with a facility cooling device.

In some embodiments, the method 1100 includes an act 1120 of flowing the cooled supply coolant to a cold inlet of a cold cooling structure of a cold plate assembly. In some embodiments, the cold cooling structure cools a cold temperature section of the computing device based on flowing the cooled supply coolant to the cold cooling structure. In some embodiments, the cooled supply coolant is flowed in parallel to a plurality of cold cooling structures of a plurality of cold plate assemblies.

In some embodiments, the method 1100 includes an act 1130 of flowing an intermediate coolant from a cold outlet of the cold cooling structure to a warm inlet of a warm cooling structure of the cold plate assembly connected to the cold cooling structure. In some embodiments, the warm cooling structure cools a warm temperature section of the computing device based on flowing the intermediate coolant to the warm cooling structure.

In some embodiments, the method 1100 includes an act 1140 of flowing a return coolant from a warm outlet of the warm cooling structure to the facility cooling device. In some embodiments, a portion of the return coolant is mixed with the intermediate coolant to produce the intermediate coolant at a supply temperature of the warm cooling structure. For example, a portion of the return coolant may flow to the mixing valve and a portion of the return coolant may flow to the facility cooling device. In some embodiments, the supply temperature of the warm cooling structure is less than a return temperature of the cold cooling structure. In some embodiments, the return coolant is flowed to the facility cooling device in parallel from a plurality of warm cooling structures of a plurality of cold plate assemblies.

In some embodiments, the method 1100 corresponds with the coolant system 650 described herein in connection with FIG. 6. The method 1100 may apply to any other coolant system.

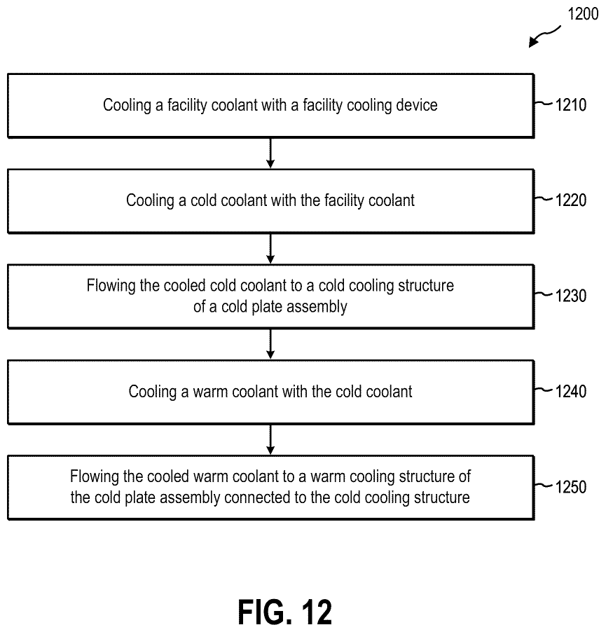

FIG. 12 illustrates a flow diagram for a method 1200 or a series of acts for cooling a computing device having a first temperature section and a second temperature section as described herein, according to at least one embodiment of the present disclosure. While FIG. 12 illustrates acts according to one embodiment, alternative embodiments may omit, add to, reorder, or modify any of the acts shown in FIG. 12.

In some embodiments, the method 1200 includes an act 1210 of cooling a facility coolant with a facility cooling device.

In some embodiments, the method 1200 includes an act 1220 of cooling a cold coolant with the facility coolant. For example, the cold coolant may be cooled by rejecting heat from the cold coolant to the facility coolant with a heat pump.

In some embodiments, the method 1200 includes an act 1230 of flowing the cooled cold coolant to a cold cooling structure of a cold plate assembly. In some embodiments, the cold cooling structure cools a cold temperature section of the computing device based on flowing the cooled cold coolant to the cold cooling structure. In some embodiments, the cooled cold coolant is flowed in parallel to a plurality of cold cooling structures of a plurality of cold plate assemblies.

In some embodiments, the method 1200 includes an act 1240 of cooling a warm coolant with the cold coolant. For example, the warm coolant may be cooled by transferring heat from the warm coolant to the cold coolant with a heat exchanger. In some embodiments, heat is transferred from a return of the warm coolant to a supply of the cold coolant.

In some embodiments, the method 1200 includes an act 1250 of flowing the cooled warm coolant to a warm cooling structure of a cold plate assembly connected to the cold cooling structure. In some embodiments, the warm cooling structure cools a warm temperature section of the computing device based on flowing the cooled warm coolant to the warm cooling structure. In some embodiments, the cooled warm coolant is flowed in parallel to a plurality of warm cooling structures of a plurality of cold plate assemblies.

In some embodiments, the method 1200 corresponds with the coolant system 550 described herein in connection with FIG. 5. The method 1200 may apply to any other coolant system.

### INDUSTRIAL APPLICABILITY

The following are non-limiting examples of various embodiments of the present disclosure.

A1. A cold plate assembly for cooling a computing device, comprising:
A first cooling structure configured to provide cooling from a flow of first coolant to a first temperature section of the computing device;
a second cooling structure connected to the first cooling structure and configured to provide cooling from a flow of second coolant to a second temperature section of the computing device, the second temperature section having a lower temperature threshold than the first temperature section; and
a thermal barrier between the first cooling structure and the second cooling structure.

A2. The assembly of A1, wherein the first cooling structure is configured to receive the flow of first coolant at a first temperature from a coolant distribution unit.

A3. The assembly of A1 or A2, wherein the second cooling structure is configured to receive the flow of second coolant at a second temperature from the coolant distribution unit.

A4. The assembly of an of A1-A3, wherein the first cooling structure is connected to a first computing component of the computing device.

A5. The assembly of any of A1-A4, wherein the second cooling structure is configured to connect to the first cooling structure such that the second cooling structure contacts a second computing component of the computing device.

A6. The assembly of A5, wherein the first computing component is a computing component of a first type and the second computing component is a computing component of a second type.

A7. The assembly of A5, wherein the first computing component is a processing component and the second computing component is a memory component.

A8. The assembly of A5, wherein the first computing component and the second computing component are located on a same chip and are adjacent.

B1. A cold plate assembly for cooling a computing device, comprising:
a first cooling structure having a first coolant inlet and a first coolant outlet for connecting the first cooling structure to a first coolant loop, the first cooling structure being configured to provide cooling to a first temperature section of the computing device;
a second cooling structure connected to the first cooling structure and having a second coolant inlet and a second coolant outlet for connecting the second cooling structure to a second coolant loop at a lower temperature than the first coolant loop, the second cooling structure being configured to provide cooling to a second temperature section of the computing device, the second temperature section having a lower temperature threshold than the first temperature section; and
a thermal barrier between the first cooling structure and the second cooling structure.

B2. The assembly of B1, wherein the first coolant loop has a higher flowrate than the second coolant loop.

B3. The assembly of B1 or B2, wherein the first coolant loop has a flowrate of 1.2 LMP/kW.

B4. The assembly of any of B1-B3, wherein the second coolant loop has a flowrate of 0.5-1 LPM/kW.

B5. The assembly of any of B1-B4, wherein the first temperature section is associated with a first computing component of the computing device and the second temperature section is associated with a second computing component of the computing device.

B6. The assembly of B5, wherein the first cooling structure is connected to the first computing component and the second cooling structure is connected to the first cooling structure such that the second cooling structure contacts the second computing component.

B7. The assembly of B5, wherein the first computing component is a computing component of a first type and the second computing component is a computing component of a second type.

B8. The assembly of B7, wherein the first type of computing component is a processor and the second type of computing component is memory.

B9. The assembly of B8, wherein the memory is vertically stacked high bandwidth memory.

B10. The assembly of any of B1-B9, wherein the first temperature section dissipates more heat than the second temperature section.

B11. The assembly of any of B1-B10, wherein the first temperature section generates at least 70% of the heat of the computing component and the second temperature section generates less than 30% of the heat of the computing component.

B12. The assembly of any of B1-B11, wherein the temperature threshold of the first temperature section is 90 C or less.

B13. The assembly of any of B1-B12, wherein the temperature threshold of the second temperature section is 55 C or less.

B14. The assembly of any of B1-B13, wherein a return temperature of the second coolant loop is less than a supply temperature of the first coolant loop.

B15. The assembly of any of B1-B14, wherein a supply temperature of the first coolant loop is 40 C.

B16. The assembly of any of B1-B15, wherein a return temperature of the first coolant loop is 45 C.

B17. The assembly of B1-B16, wherein a supply temperature of the second coolant loop is 20 C.

B18. The assembly of B1-B17, wherein a return temperature of the second coolant loop is 25 C.

B19. The assembly of B1-B18, wherein the cold plate assembly is connected to the first coolant loop in parallel with one or more additional cold plate assemblies.

B20. The assembly of B1-B19, wherein the cold plate assembly is connected to the second coolant loop in parallel with one or more additional cold plate assemblies.

B21. The assembly of B1-B20, wherein the second coolant outlet is connected in series to the first coolant inlet.

B22. The assembly of B1-B21, wherein the second cooling structure is positioned at least partially on top of the first cooling structure.

B23. The assembly of B1-B22, wherein the second cooling structure is positioned at least partially around the first cooling structure.

B24. The assembly of B1-B23, wherein a fluid path from the second inlet to the second outlet traverses over the first cooling structure.

B25. The assembly of B1-B24, wherein the thermal barrier includes a low thermally conductive material.

B26. The assembly of B1-B25, wherein the low thermally conductive material is different than a material of the first cooling structure and material of the second cooling structure.

B27. The assembly of B1-B26, wherein the thermal barrier includes a high thermal resistance mechanical connection.

B28. The assembly of B27, wherein the high thermal resistance mechanical connection includes one or more bridges or bumps between the first cooling structure and the second cooling structure and one or more air gaps between the first cooling structure and the second cooling structure.

B29. The assembly of B27, wherein the thermal barrier is a same material of the first cooling structure or the second cooling structure or both.

B30. The assembly of B1-B29, wherein the first cooling structure includes microchannels configured to direct the first coolant loop to one or more high heat flux areas of the first temperature section.

B31. The assembly of B30, wherein the microchannels are configured to split the first coolant loop to flow in parallel to two or more high heat flux areas of the first temperature section.

B32. The assembly of B1-B31, wherein the second cooling structure includes microchannels, and wherein the microchannels of the first cooling structure are wider than microchannels of the first cooling structure.

B33. The assembly of B1-B32, wherein the second cooling structure includes microchannels to split the second coolant loop to flow in parallel to two or more computing components of the computing device.

B34. The assembly of B1-B33, wherein the second cooling structure is positionable with respect to the first cooling structure.

C1. A method of cooling a computing device having a first temperature section and a second temperature section, comprising:
flowing a first coolant to a first cooling structure of a cold plate assembly;
cooling the first temperature section with the first cooling structure;
flowing a second coolant to a second cooling structure of the cold plate assembly connected to the first cooling structure; and
cooling the second temperature section with the second cooling structure.

C2. The method of claim 1, wherein cooling the second temperature section includes cooling the second temperature section at a lower temperature than the first temperature section.

C3. The method of claim 1, wherein flowing the second coolant includes flowing the second coolant at a lower temperature than the first coolant.

C4. The method of claim 1, wherein flowing the second coolant includes flowing the second coolant at a lower flow rate than the first coolant.

C5. The method of claim 1, wherein the first temperature section has a higher temperature threshold than the second temperature section.

C6. The method of claim 1, further including preventing thermal conduction between the first cooling structure and the second cooling structure with a thermal barrier.

D1. A coolant system for cooling a computing device, comprising:
a first coolant loop cooled by a first facility cooling device;
a second coolant loop cooled by a second facility cooling device to a lower temperature than the first coolant loop; and
a cold plate assembly, including:
   a first cooling structure in fluid communication with the first coolant loop and configured to provide cooling to a first temperature section of the computing device;
   a second cooling structure connected to the first cooling structure and in fluid communication with the second coolant loop, the second cooling structure being configured to provide cooling to a second temperature section of the computing device, the second temperature section having a lower temperature threshold than the first temperature section; and
   a thermal barrier between the first cooling structure and the second cooling structure.

E1. A coolant system for cooling a computing device, comprising:
a first coolant loop cooled by a first facility cooling device;
a second coolant loop cooled by a second facility cooling device to a lower temperature than the first coolant loop; and
a cold plate assembly, including:
   a first cooling structure in fluid communication with the first coolant loop and configured to provide cooling to a first temperature section of the computing device;
   a second cooling structure connected to the first cooling structure and in fluid communication with the second coolant loop, the second cooling structure being configured to provide cooling to a second temperature section of the computing device, the second temperature section having a lower temperature threshold than the first temperature section; and
   a thermal barrier between the first cooling structure and the second cooling structure.

E2. The system of E1, wherein the first facility cooling device is more energy efficient than the second facility cooling device.

E3. The system of E1 or E2, wherein the second facility cooling device is capable of cooling to a lower temperature than the first facility cooling device.

E4. The system of any of E1-E3, wherein the first facility cooling device is a fin-fan cooler.

E5. The system of any of E1-E4, wherein the second facility cooling device is a chiller.

E6. The system of any of E1-E5, wherein the first coolant loop has a higher flow rate than the second coolant loop.

E7. The system of any of E1-E6, wherein the cold plate assembly is connected to the first coolant loop and the second coolant loop in parallel with one or more additional cold plate assemblies.

F1. A coolant system for cooling a computing device, comprising:
a first coolant loop cooled by a facility cooling device;
a second coolant loop cooled by a heat pump and cooled to a lower temperature than the first coolant loop; and
a cold plate assembly, including:
   a first cooling structure in fluid communication with the first coolant loop and configured to provide cooling to a first temperature section of the computing device;
   a second cooling structure connected to the first cooling structure and in fluid communication with the second coolant loop, the second cooling structure being configured to provide cooling to a second temperature section of the computing device, the second temperature section having a lower temperature threshold than the first temperature section; and
   a thermal barrier between the first cooling structure and the second cooling structure.

F2. The system of F1, wherein the heat pump is configured to reject heat from the second coolant loop to the first coolant loop.

F3. The system of F1 or F2, wherein the heat pump is in thermal communication with the first coolant loop between the facility cooling device and an outlet of the first cooling structure.

F4. The system of any of F1-F3, wherein the heat pump is in thermal communication with the second coolant loop between an outlet of the second cooling structure and an inlet of the second cooling structure.

F5. The system of any of F1-F4, wherein the heat pump is configured to reject heat from a second return coolant of the second coolant loop at a second return temperature to a first return coolant of the first coolant loop at a first return temperature, and wherein a second return temperature is less than the first return temperature.

F6. The system of any of F1-F5, wherein the facility cooling device is air cooled and is a dry cooler.

F7. The system of any of F1-F6, wherein the computing device is implemented in a server and wherein the heat pump is implemented in the server.

F8. The system of any of F1-F7, wherein the heat pump is implemented in a coolant distribution unit, and wherein the computing device is implemented in a server connected to the coolant distribution unit.

F9. The system of F8, further comprising one or more additional cold plate assemblies connected to the first coolant loop and the second coolant loop in parallel.

F10. The system of F9, wherein each of the one or more additional cold plate assemblies are implemented in a server, and wherein each server is connected in parallel to the coolant distribution unit.

G1. A coolant system for cooling a computing device, comprising:
a coolant supply for flowing a supply coolant;
a coolant return for flowing a return coolant;
a cold plate assembly including:
   a cold cooling structure configured to provide cooling to a cold temperature section of the computing device, the cold cooling structure having a cold inlet in fluid communication with the coolant supply, and a cold outlet;
   a warm cooling structure connected to the cold cooling structure and configured to provide cooling to a warm temperature section of the computing device, the warm temperature section having a higher temperature threshold than the cold temperature section, the warm cooling structure having a warm outlet in fluid communication with the coolant return, and a warm inlet;
   a thermal barrier between the cold cooling structure and the warm cooling structure;
an intermediate coolant loop in fluid communication with the cold outlet and the warm inlet for flowing an intermediate coolant from the cold outlet to the warm inlet; and
a mixing valve in fluid communication with the coolant return and the intermediate coolant loop.

G2. The system of G1, further comprising a facility cooling device for cooling the return coolant at a return temperature to a supply temperature of the supply coolant.

G3. The system of G2, wherein a portion of the return coolant flows to the mixing valve and a portion of the return coolant flows to the facility cooling device.

G4. The system of G2, wherein the facility cooling device includes one or more of a chiller and a cooling tower.

G5. The system of any of G1-G4, wherein the mixing valve is configured to mix at least some of the return coolant with the intermediate coolant to cool the intermediate coolant.

G6. The system of any of G1-G5, wherein a coolant temperature from the cold outlet is less than a coolant temperature to the warm inlet.

G7. The system of any of G1-G6, wherein a coolant flow rate to the warm inlet is greater than a coolant flow rate from the cold outlet.

H1. A coolant system for cooling a computing device, comprising:
a cold coolant loop;
a warm coolant loop;
a facility coolant loop cooled by a facility cooling device and configured to cool the cold coolant loop;
a cold plate assembly, including:
   a first cooling structure in fluid communication with the warn coolant loop and configured to provide cooling to a first temperature section of the computing device;
   a second cooling structure connected to the first cooling structure and in fluid communication with the cold coolant loop, the second cooling structure being configured to provide cooling to a second temperature section of the computing device, the second temperature section having a lower temperature threshold than the first temperature section; and
   a thermal barrier between the first cooling structure and the second cooling structure.

H2. The system of H1, further including a heat pump, and wherein the facility coolant loop is configured to cool the cool coolant loop by rejecting heat from the cold coolant loop to the facility coolant loop via the heat pump.

H3. The system of H1 or H2, wherein the warm coolant loop is configured to be cooled by the cold coolant loop.

H4. The system of any of H1-H3, further including a heat exchanger, wherein the heat exchanger is configured to reject heat from a return of the warm coolant loop to a supply of the cold coolant loop to cool the warm coolant loop.

H5. The system of any of H1-H4, wherein the facility cooling device is a fin-fan cooler.

I1. A method of cooling a computing device, comprising:
cooling a first coolant with a first facility cooling device;
flowing the cooled first coolant to a first cooling structure of a cold plate assembly;
cooling a second coolant with a second facility cooling device; and
flowing the cooled second coolant to a second cooling structure of the cold plate assembly connected to the first cooling structure.

I2. The method of I1, wherein cooling the second coolant includes cooling the second coolant to a lower temperature than the first coolant is cooled.

I3. The method of I1 or I2, wherein flowing the first coolant includes flowing the first coolant at a higher flow rate than the second coolant.

I4. the method of any of I1-I3, further comprising cooling a first temperature section of the computing device with the first cooling structure based on flowing the cooled first coolant to the first cooling structure.

I5. The method of any of I1-I4, further comprising cooling a second temperature section of the computing device with the second cooling structure based on flowing the cooled second coolant to the second cooling structure.

I6. The method of I1-I5, wherein flowing the cooled first coolant includes flowing the first cooled coolant in parallel to a plurality of first cooling structures of a plurality of cold plate assemblies.

I7. The method of any of I1-I6, wherein flowing the cooled second coolant includes flowing the second cooled coolant in parallel to a plurality of second cooling structures of a plurality of cold plate assemblies.

J1. A method of cooling a computing device, comprising:
cooling a first coolant with a facility cooling device;
flowing the cooled first coolant to a first cooling structure of a cold plate assembly;
cooling a second coolant with a return of the first coolant; and
flowing the cooled second coolant to a second cooling structure of the cold plate assembly connected to the first cooling structure.

J2. The method of J1, wherein the return of the first coolant is a higher temperature than the second coolant.

J3. The method of J1 or J2, wherein cooling the second coolant includes rejecting heat from the second coolant to the return of the first coolant with a heat pump.

J4. the method of any of J1-J3, further comprising cooling a first temperature section of the computing device with the first cooling structure based on flowing the cooled first coolant to the first cooling structure.

J5. The method of any of J1-J4, further comprising cooling a second temperature section of the computing device with the second cooling structure based on flowing the cooled second coolant to the second cooling structure.

J6. The method of J1-J5, wherein flowing the cooled first coolant includes flowing the first cooled coolant in parallel to a plurality of first cooling structures of a plurality of cold plate assemblies.

J7. The method of any of J1-J6, wherein flowing the cooled second coolant includes flowing the second cooled coolant in parallel to a plurality of second cooling structures of a plurality of cold plate assemblies.

K1. A method of cooling a computing device, comprising:
cooling a supply coolant with a facility cooling device;
flowing the cooled supply coolant to a cold inlet of a cold cooling structure of a cold plate assembly;
flowing an intermediate coolant from a cold outlet of the cold cooling structure to a warm inlet of a warm cooling structure of the cold plate assembly connected to the cold cooling structure; and
flowing a return coolant from a warm outlet of the warm cooling structure to the facility cooling device.

K2. The method of K1, further comprising mixing a portion of the return coolant with the intermediate coolant with a mixing valve to produce the intermediate coolant at a supply temperature of the warm cooling structure.

K3. The method of K2, wherein the supply temperature of the warm cooling structure is less than a return temperature of the cold cooling structure.

K4. The method of K2 or K3, further comprising flowing a portion of the return coolant to the mixing valve and flowing a portion of the return coolant to the facility cooling device.

K5. the method of any of K1-K4, further comprising cooling a cold temperature section of the computing device with the cold cooling structure based on flowing the cooled supply coolant to the cold cooling structure.

K6. The method of any of K1-K5, further comprising cooling a warm temperature section of the computing device with the warm cooling structure based on flowing the intermediate coolant to the warm cooling structure.

K7. The method of any of K1-K6, wherein flowing the cooled supply coolant includes flowing the cooled supply coolant in parallel to a plurality of cold cooling structures of a plurality of cold plate assemblies.

K8. The method of any of K1-K7, wherein flowing the return coolant includes flowing the return coolant in parallel from a plurality of warm cooling structures of a plurality of cold plate assemblies.

L1. A method of cooling a computing device, comprising:
cooling a facility coolant with a facility cooling device;
cooling a cold coolant the facility coolant;
flowing the cooled cold coolant to a cold cooling structure of a cold plate assembly; cooling a warm coolant with the cold coolant; and
flowing the cooled warm coolant to a warm cooling structure of a cold plate assembly connected to the cold cooling structure.

L2. The method of L1, wherein cooling the cold coolant includes rejecting heat from the cold coolant to the facility coolant with a heat pump.

L3. The method of L1 or L2, wherein cooling the warm coolant includes transferring heat from the warm coolant to the cold coolant with a heat exchanger.

L4. The method of L3, wherein transferring heat from the warm coolant includes transferring heat from a return of the warm coolant to a supply of the cold coolant.

L5. The method of any of L1-L4, further comprising cooling a cold temperature section of the computing device with the cold cooling structure based on flowing the cooled cold coolant to the cold cooling structure.

L6. The method of any of L1-L5, further comprising cooling a warm temperature section of the computing device with the warm cooling structure based on flowing the cooled warm coolant to the warm cooling structure.

L7. The method of any of L1-L6, wherein flowing the cooled cold coolant includes flowing the cooled cold coolant in parallel to a plurality of cold cooling structures of a plurality of cold plate assemblies.

L8. The method of any of L1-L7, wherein flowing the cooled warm coolant includes flowing the cooled warm coolant in parallel to a plurality of warm cooling structures of a plurality of cold plate assemblies.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A cooling system for cooling a computing device, comprising:
a first coolant loop cooled by a first facility cooling device;
a second coolant loop cooled by a second facility cooling device to a lower temperature than the first coolant loop; and
a cold plate assembly, including:
a first cooling structure in fluid communication with the first coolant loop and configured to provide cooling to a first temperature section of the computing device;
a second cooling structure connected to the first cooling structure and in fluid communication with the second coolant loop, the second cooling structure being configured to provide cooling to a second temperature section of the computing device, the second temperature section having a lower temperature threshold than the first temperature section; and
a thermal barrier between the first cooling structure and the second cooling structure.

2. The system of claim 1, wherein the first facility cooling device is more energy efficient than the second facility cooling device.

3. The system of claim 1, wherein the second facility cooling device is capable of cooling to a lower temperature than the first facility cooling device.

4. The system of claim 1, wherein the first facility cooling device is a fin-fan cooler.

5. The system of claim 1, wherein the second facility cooling device is a chiller.

6. The system of claim 1, wherein the first coolant loop has a higher flow rate than the second coolant loop.

7. The system of claim 1, wherein the cold plate assembly is connected to the first coolant loop and the second coolant loop in parallel with one or more additional cold plate assemblies.

8. A cooling system for cooling a computing device, comprising:
a first coolant loop cooled by a facility cooling device;
a second coolant loop cooled by a heat pump and cooled to a lower temperature than the first coolant loop; and
a cold plate assembly, including:
a first cooling structure in fluid communication with the first coolant loop and configured to provide cooling to a first temperature section of the computing device;
a second cooling structure connected to the first cooling structure and in fluid communication with the second coolant loop, the second cooling structure being configured to provide cooling to a second temperature section of the computing device, the second temperature section having a lower temperature threshold than the first temperature section; and
a thermal barrier between the first cooling structure and the second cooling structure.

9. The system of claim 8, wherein the heat pump is configured to reject heat from the second coolant loop to the first coolant loop.

10. The system of claim 8, wherein the heat pump is in thermal communication with the first coolant loop between the facility cooling device and an outlet of the first cooling structure.

11. The system of claim 8, wherein the heat pump is in thermal communication with the second coolant loop between an outlet of the second cooling structure and an inlet of the second cooling structure.

12. The system of claim 8, wherein the heat pump is configured to reject heat from a second return coolant of the second coolant loop at a second return temperature to a first return coolant of the first coolant loop at a first return temperature, and wherein a second return temperature is less than the first return temperature.

13. The system of claim 8, wherein the facility cooling device is air cooled and is a dry cooler.

14. The system of claim 8, wherein the computing device is implemented in a server and wherein the heat pump is implemented in the server.

15. The system of claim 8, wherein the heat pump is implemented in a coolant distribution unit, and wherein the computing device is implemented in a server connected to the coolant distribution unit.

16. The system of claim 15, further comprising one or more additional cold plate assemblies connected to the first coolant loop and the second coolant loop in parallel.

17. The system of claim 16, wherein each of the one or more additional cold plate assemblies are implemented in a server, and wherein each server is connected in parallel to the coolant distribution unit.

18. A cooling system for cooling a computing device, comprising:
a coolant supply for flowing a supply coolant;
a coolant return for flowing a return coolant;
a cold plate assembly including:
a cold cooling structure configured to provide cooling to a cold temperature section of the computing device, the cold cooling structure having a cold inlet in fluid communication with the coolant supply, and a cold outlet;
a warm cooling structure connected to the cold cooling structure and configured to provide cooling to a warm temperature section of the computing device, the warm temperature section having a higher temperature threshold than the cold temperature section, the warm cooling structure having a warm outlet in fluid communication with the coolant return, and a warm inlet;
a thermal barrier between the cold cooling structure and the warm cooling structure;
an intermediate coolant loop in fluid communication with the cold outlet and the warm inlet for flowing an intermediate coolant from the cold outlet to the warm inlet; and
a mixing valve in fluid communication with the coolant return and the intermediate coolant loop.

19. The system of claim 18, further comprising a facility cooling device for cooling the return coolant at a return temperature to a supply temperature of the supply coolant.

20. The system of claim 19, wherein a portion of the return coolant flows to the mixing valve and a portion of the return coolant flows to the facility cooling device.

21. The system of claim 19, wherein the facility cooling device includes one or more of a chiller and a cooling tower.

22. The system of claim 18, wherein the mixing valve is configured to mix at least some of the return coolant with the intermediate coolant to cool the intermediate coolant.

23. The system of claim 18, wherein a coolant temperature from the cold outlet is less than a coolant temperature to the warm inlet.

24. The system of claim 18, wherein a coolant flow rate to the warm inlet is greater than a coolant flow rate from the cold outlet.
